(19) United States
(12) Patent Application Publication
(10) Pub. No.: US 2026/0005045 A1
(43) Pub. Date: Jan. 1, 2026

(54) CHAMBER ARRANGEMENTS WITH OFFSET HEATER ELEMENT ARRAYS, SEMICONDUCTOR PROCESSING SYSTEMS, AND METHODS OF MAKING CHAMBER ARRANGEMENTS AND DEPOSITION MATERIAL LAYERS ONTO SUBSTRATES

(71) Applicant: ASM IP Holding B.V., Almere (NL)

(72) Inventors: Caleb Miskin, Mesa, AZ (US); Robinson James, Phoenix, AZ (US); Nitin Choudhary, Mesa, AZ (US); Bubesh Babu Jotheeswaran, Gilbert, AZ (US); Alexandros Demos, Scottsdale, AZ (US); Nayna Khosla, Tempe, AZ (US); Mitisha Surana, Tempe, AZ (US); Han Ye, Phoenix, AZ (US); Wentao Wang, Chandler, AZ (US); Ion Hong Chao, Gilbert, AZ (US); Fan Gao, Chandler, AZ (US); Junwei Su, Chandler, AZ (US)

(21) Appl. No.: 19/249,240

(22) Filed: Jun. 25, 2025

Related U.S. Application Data
(60) Provisional application No. 63/665,062, filed on Jun. 27, 2024.
(60) Provisional application No. 63/665,070, filed on Jun. 27, 2024.

(51) Int. Cl. H01L 21/67; C23C 16/46

(52) U.S. Cl. CPC H01L 21/67115; C23C 16/46; H01L 21/67248

(57) ABSTRACT

A chamber arrangement includes a chamber body, a substrate support, and an upper heater element array. The chamber body has injection and longitudinally opposite exhaust ends, the substrate support is arranged within the chamber body and supported therein for rotation about a rotation axis, and the upper heater element array is supported above the chamber body and include a laterally-inner first upper linear lamp and a laterally-inner second upper linear lamp. The laterally-inner first upper linear lamp is separated from the rotation axis by a first lateral spacing distance, the laterally-inner second upper linear lamp is separated from the rotation axis by a second lateral spacing distance, and one of the first lateral spacing distance and the second lateral spacing distance is greater than the other of the first lateral spacing distance the second lateral spacing distance. Semiconductor processing systems and material layer deposition methods are also described.

### CROSS-REFERENCE TO RELATED APPLICATIONS

This application claims priority to and the benefits of U.S. Provisional Patent Application No. 63/665,070 and U.S. Provisional Patent Application No. 63/665,062, both filed on Jun. 27, 2024, the contents of which is incorporated herein by reference in their entireties.

### FIELD OF INVENTION

The present disclosure generally relates to depositing material layers onto substrates, and more particular to controlling substrate temperature during deposition of material layers onto substrates.

### BACKGROUND OF THE DISCLOSURE

Material layers are commonly deposited onto substrates such as during the fabrication of semiconductor devices. Deposition may be accomplished by loading a substrate into a reactor, heating the substrate, and contacting the heated substrate with a material layer precursor under conditions selected to cause a material layer to deposit onto the substrate. Heating of the substrate is typically controlled during deposition such that the material layer forms with one or more desired property, such as with a desired thickness and/or compositional uniformity across the substrate. As semiconductor devices become progressively smaller, additional and/or improved temperature control techniques and reactor temperature control features are necessary to ensure that the material layers deposited onto substrates and employed for fabricating semiconductor devices have properties suitable for the semiconductor device being fabricated.

Such systems and methods have generally been considered suitable for their intended purpose. However, there remains a need in the art for improved chamber arrangements, semiconductor processing systems including chamber arrangements, and related material layer deposition methods. The present disclosure provides a solution to this need.

### SUMMARY OF THE DISCLOSURE

A chamber arrangement is provided. The chamber arrangement includes a chamber body, a substrate support, and an upper heater element array. The chamber body has an injection end and a longitudinally opposite exhaust end, the substrate support is arranged within the chamber body and supported therein for rotation about a rotation axis, and the upper heater element array is supported above the chamber body and include a laterally-inner first upper linear lamp and a laterally-inner second upper linear lamp. The laterally-inner first upper linear lamp is separated from the rotation axis by a first lateral spacing distance, the laterally-inner second upper linear lamp is separated from the rotation axis by a second lateral spacing distance, and one of the first lateral spacing distance and the second lateral spacing distance is greater than the other of the first lateral spacing distance the second lateral spacing distance.

In addition to one or more of the features described above, or as an alternative, further examples of the chamber arrangement may include that the chamber body has one or more external rib extending about an exterior of the chamber body and longitudinally between the injection end and the exhaust end of the chamber body.

In addition to one or more of the features described above, or as an alternative, further examples of the chamber arrangement may include that the laterally-inner first upper linear lamp and the laterally-inner second upper linear lamp are substantially orthogonal to the one or more external rib.

In addition to one or more of the features described above, or as an alternative, further examples of the chamber arrangement may include a lower heater element array including two or more filament-type lower linear lamps supported below the chamber body. The two or more filament-type lower linear lamps are substantially parallel to the one or more external rib.

In addition to one or more of the features described above, or as an alternative, further examples of the chamber arrangement may include that the upper heater element array is laterally offset from to the rotation axis. Alternatively (or additionally), the upper heater element array may be longitudinally offset from the rotation axis.

In addition to one or more of the features described above, or as an alternative, further examples of the chamber arrangement may include an upper reflector supported above the chamber body. The upper heater element array may be fixed relative to the chamber body, wherein the upper reflector is supported for movement relative to the chamber body.

In addition to one or more of the features described above, or as an alternative, further examples of the chamber arrangement may include that the chamber body has one or more external rib extending about an exterior of the chamber body and longitudinally between the injection end and the exhaust end of the chamber body.

In addition to one or more of the features described above, or as an alternative, further examples of the chamber arrangement may include that the laterally-inner first upper linear lamp and the laterally-inner second upper linear lamp are substantially orthogonal to the one or more external rib.

In addition to one or more of the features described above, or as an alternative, further examples of the chamber arrangement may include a lower heater element array including two or more filament-type lower linear lamps supported below the chamber body. The two or more filament-type lower linear lamps are substantially parallel to the one or more external rib.

In addition to one or more of the features described above, or as an alternative, further examples of the chamber arrangement may include a first substrate pyrometer supported above the chamber body and arranged along a first substrate pyrometer optical axis. The first substrate pyrometer optical axis may intersect the substrate support. The first substrate pyrometer optical axis may extend between the laterally-inner first upper linear lamp and the laterally-inner second upper linear lamp.

In addition to one or more of the features described above, or as an alternative, further examples of the chamber arrangement may include a longitudinally-inner first lower linear lamp supported below the chamber body and a longitudinally-inner second lower linear lamp. The first substrate pyrometer optical axis may extend between the longitudinally-inner first lower linear lamp and the longitudinally-inner second lower linear lamp.

In addition to one or more of the features described above, or as an alternative, further examples of the chamber arrangement may include a second substrate pyrometer supported above the chamber body and arranged along a second substrate pyrometer optical axis. The second substrate pyrometer optical axis may intersect the substrate support. The second substrate pyrometer optical axis may extend between the laterally-inner first upper linear lamp and the laterally-inner second upper linear lamp.

In addition to one or more of the features described above, or as an alternative, further examples of the chamber arrangement may include a longitudinally-outer first lower linear lamp supported below the chamber body and a longitudinally-intermediate second lower linear lamp supported below the chamber body. The longitudinally-intermediate second lower lamp may separate the longitudinally-outer first lower linear lamp from the rotation axis. The second substrate pyrometer optical axis may extend between the longitudinally-outer first lower linear lamp and the longitudinally-intermediate second lower linear lamp.

In addition to one or more of the features described above, or as an alternative, further examples of the chamber arrangement may include a third substrate pyrometer supported above the chamber body and arranged along a third substrate pyrometer optical axis. A longitudinally-inner first lower linear lamp may be supported below the chamber body. A longitudinally-inner second lower linear lamp may be supported below the chamber body and separated from the longitudinally-inner first lower linear lamp by the rotation axis. The third substrate pyrometer optical axis may separate the longitudinally-inner first lower linear lamp from the longitudinally-inner second lower linear lamp. The third substrate pyrometer optical axis may be separated from the laterally-inner second upper linear lamp by the laterally-inner first upper linear lamp.

In addition to one or more of the features described above, or as an alternative, further examples of the chamber arrangement may include that the chamber body has an upper wall and an upper rib portion formed from a singular one-piece ceramic workpiece using a subtractive manufacturing technique. Alternatively (or additionally), the chamber body has a lower wall and a lower rib portion formed from a singular one-piece ceramic workpiece using a subtractive manufacturing technique.

In addition to one or more of the features described above, or as an alternative, further examples of the chamber arrangement may include that the upper heater element array includes two or more filament-type upper linear lamps. The chamber arrangement may further include a lower heater element array supported below the chamber body. The lower heater element array may include two or more filament-type lower linear lamps. The two or more filament-type lower linear lamps of the lower heater element array may be greater than the two or more filament-type upper linear lamps of the upper heater element array.

In addition to one or more of the features described above, or as an alternative, further examples of the chamber arrangement may include that the upper reflector is fully parabolic, an entirety of the reflective surface opposing the chamber body being occupied by a plurality of arcuate recesses in such examples. The lower reflector may be a fully parabolic, substantially of a reflective surface of the lower reflector occupied by arcuate recesses.

In addition to one or more of the features described above, or as an alternative, further examples of the chamber arrangement may include that the chamber body defines a lower chamber height between a lower surface of the substrate support and an interior surface of a wall of the chamber body, an upper chamber height between an upper surface of the substrate support, and that the lower chamber height is less than the upper chamber height of the upper chamber.

IA semiconductor processing system is provided. The semiconductor processing system includes a chamber arrangement as described above and a controller. The chamber arrangement further includes a first substrate pyrometer supported above the chamber body and arranged along a first substrate pyrometer optical axis intersecting the substrate support, a second substrate pyrometer supported above the chamber body and arranged along a second substrate pyrometer optical axis intersecting the substrate support, and a third substrate pyrometer supported above the chamber body and arranged along a third substrate pyrometer optical axis intersecting the substrate support. The controller is disposed in communication with the first substrate pyrometer, the second substrate pyrometer and the third substrate pyrometer. The controller is further responsive to instructions recorded on a memory to operably couple the first substrate pyrometer to three (3) laterally adjacent upper linear lamps of the upper heater element array including the laterally-inner first upper linear lamp and the laterally-inner second upper linear lamp, operably couple the second substrate pyrometer to a laterally-outer first upper linear lamp and a laterally-outer second upper linear lamp of the upper heater element array, and operably couple the third substrate pyrometer to a laterally-intermediate second upper linear lamp of the upper heater element array. The instructions may further cause the controller to deposit a material layer onto a substrate within the chamber body while controlling temperature of the substrate using electromagnetic radiation emitted by the substrate and the material layer received at the first substrate pyrometer, the second substrate pyrometer, and the third substrate pyrometer during deposition of the material layer onto the substrate.

In addition to one or more of the features described above, or as an alternative, further examples of the semiconductor processing system may include that the instructions further cause the controller to throttle heating of the substrate using eleven (11) non-overlapping locations laterally spaced from one another above the substrate and between a first sidewall and a second sidewall of the chamber body.

In addition to one or more of the features described above, or as an alternative, further examples of the semiconductor processing system may include that the chamber arrangement further includes a lower heater element array including two or more filament-type lower linear substantially orthogonal to a plurality of filament-type upper linear lamps of the upper heater element array. The instructions recorded on the memory may further cause the controller to operably couple the first substrate pyrometer to a longitudinally-inner first lower linear lamp and a longitudinally-inner second lower linear lamp of the lower heater element array, operably couple the second substrate pyrometer to a longitudinally-outer first lower linear lamp and a longitudinally-outer second lower linear lamp of the lower heater element array, and operably couple the third substrate pyrometer to a longitudinally-intermediate first lower linear lamp and a longitudinally-intermediate second lower linear lamp.

In addition to one or more of the features described above, or as an alternative, further examples of the semiconductor processing system may include that the instructions cause the controller to throttle heating of the substrate using twelve (12) locations longitudinally spaced apart from one another below the substrate and between the injection end and the exhaust end of the chamber body.

A material layer deposition method is provided. The method includes, at a chamber arrangement as described above, seating a substrate on the substrate support, heating the substrate using the upper heater element array, contacting the substrate with a material layer precursor, and depositing a material layer onto the using the material layer precursor. The substrate is heated using eleven (11) filament-type upper linear heating elements offset from the rotation axis unequal lateral offsets from the rotation axis and cross-substrate material layer thickness variation with the material layer deposited onto the substrate is less than that of a material layer deposited using a chamber arrangement having filament-type upper heater elements with two or more equivalent lateral offsets.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a chamber arrangement in accordance with the present disclosure, showing the chamber arrangement coupling a process fluid source to an exhaust source and a controller;

FIG. 2 is a schematic view of the semiconductor processing system of FIG. 1 including the process fluid source and the controller according to an example of the disclosure, schematically showing material layer precursor sources of the process fluid source;

FIG. 3 is a cross-sectional side view of the chamber arrangement of FIG. 1 according to an example of the present disclosure, schematically showing reflectors and lamp arrays supported above and below a chamber body of the chamber arrangement;

FIGS. 4 and 5 are end and plan views of a portion of the chamber arrangement of FIG. 1 according to an example of the disclosure, schematically showing an upper heater element array and an upper reflector supported above the chamber body of the chamber arrangement;

FIGS. 6 and 7 are side and plan views of a portion of the chamber arrangement of FIG. 1 according to an example of the disclosure, schematically showing a lower heater element array and a lower reflector supported below the chamber body of the chamber arrangement;

FIGS. 8-10 are plan views of the upper reflector of the chamber arrangement of FIG. 1 according to an example of the disclosure, schematically showing the positioning of the upper reflector and upper linear lamps depending therefrom such that the upper linear lamps are asymmetrically distributed laterally relative to the rotation axis;

FIG. 11 is a partial view of a portion of the chamber arrangement of FIG. 1 according to an example of the disclosure, schematically showing the controller operatively coupling pyrometers to upper and lower linear heater element arrays of the chamber arrangement;

FIG. 12 is a block diagram of a material layer deposition method using the chamber arrangement of FIG. 1 according to an example of the disclosure, showing operations of the method according to an illustrative and non-limiting example of the method;

FIGS. 13-15 are block diagrams of operations of the method of FIG. 14 according to examples of the disclosure, showing substrate temperature measurements acquired by the pyrometers being employed to control temperature of a substrate seated within a chamber arrangement;

FIG. 16 is a graph set of cross-substrate material layer thickness variation within silicon material layers and silicon germanium material layers deposited within the chamber arrangement of FIG. 1 and a chamber arrangement having a different arrangement, comparatively showing reduced material layer variation in material layers deposited using the chamber arrangement of FIG. 1 relative to the chamber arrangement having the different arrangement; and

FIG. 17 is a graph set of material layer thickness change responsive to common commanded temperature changes locally at center, intermediate, and peripheral regions of a substrate, showing correspondence of the commanded temperature change to actual temperature change through material layer thickness change.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

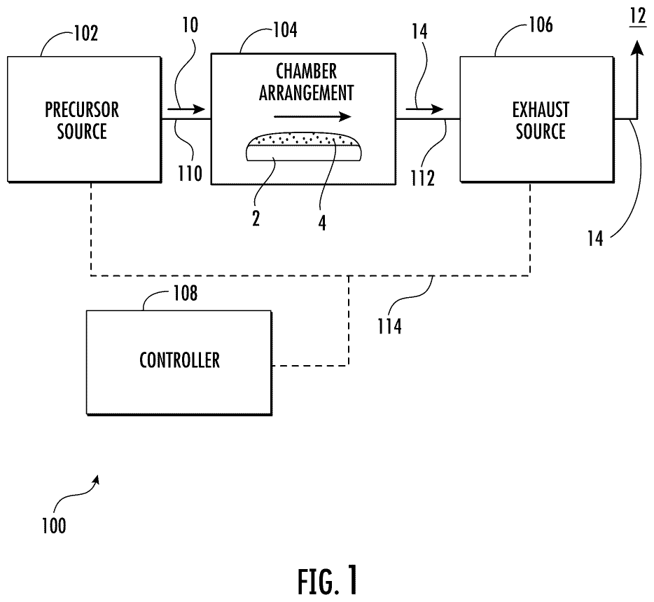

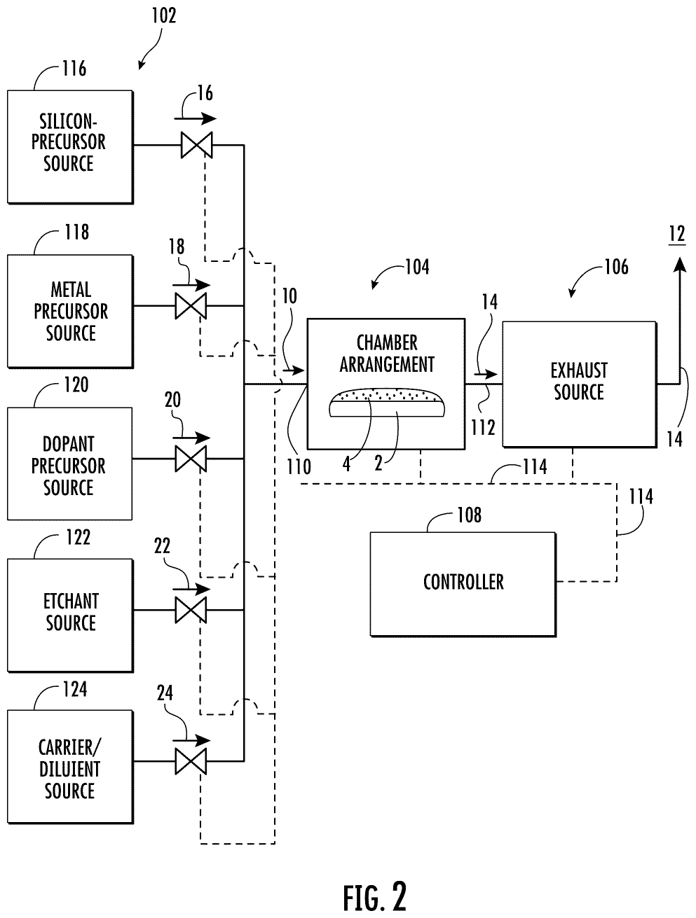

Reference will now be made to the drawings wherein like reference numerals identify similar structural features or aspects of the subject disclosure. For purposes of explanation and illustration, and not limitation, a partial view of an example of a semiconductor processing system including a chamber arrangement in accordance with the present disclosure is shown in FIG. 1 and is designated generally by reference character 100. Other examples of chamber arrangements, semiconductor processing systems including chamber arrangements, and related material layer deposition methods in accordance with the present disclosure, or aspects thereof, are provided in FIGS. 2-17, as will be described. The systems and methods of the present disclosure may be control substrate temperature during deposition of material layers onto substrates, such as during the deposition of silicon-containing material layers onto substrates in chamber arrangements having single wafer cross-flow architectures, though the present disclosure is not limited any particular type of material layer or chamber architecture in general.

Referring to FIG. 1, the semiconductor processing system 100 is shown. The semiconductor processing system 100 generally includes a process fluid source 102, a chamber arrangement 104, an exhaust source 106, and a controller 108. The process fluid source 102 is coupled to the chamber arrangement 104 by a process fluid supply conduit 110, includes a process fluid 10, and is configured to communicate a process fluid flow including the process fluid 10 to the chamber arrangement 104. The chamber arrangement 104 is coupled to the exhaust source 106 by an exhaust conduit 112 and is configured to contact a substrate 2 supported within the chamber arrangement 104 under environmental conditions (e.g., temperature and pressure) selected to cause a material layer 4 to deposit onto the substrate 2. The exhaust source 106 is in fluid communication with an external environment 12 outside of the semiconductor processing system 100 and is configured to communicate thereto an exhaust flow including residual process fluid and/or reactants 14 to the external environment 12. In this respect it is contemplated that the exhaust source 106 include one or more of a vacuum pump and an abatement device such as a burn box and/or a scrubber. The controller 108 is operatively coupled to one or more of the process fluid source 102, the chamber arrangement 104, and/or the exhaust source 106 to control deposition of the material layer 4 onto the substrate 2. In this respect it is contemplated that the controller 108 may be communicatively coupled to one or more element of the chamber arrangement 104 by a wired or wireless link 114.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

As has been explained above, in some material layer deposition processes, variation in substrate heating may induce variation in one more properties of a material layer deposited onto to substrate. For example, variation in substrate heating may induce cross-substrate material layer thickness variation and thickness non-uniformity. Variation in substrate heating may also induce cross-substrate composition variation and non-uniformity. And variation in substrate heating may further induce variation in cross-substrate material layer resistivity, such as due to dopant concentration variation. To limit substrate heating variation of the substrate 2 during deposition of the material layer 4 onto the substrate 2, for example to limit cross-substrate variation in one or property of the material layer 4 deposited onto the substrate 2, and/or to provide further advantages, the chamber arrangement 104 is provided.

With reference to FIG. 2, the process fluid source 102 and the controller 108 are shown according to an example of the disclosure. In the illustrated example the process fluid source 102 is configured to communicate one or more precursor via the process fluid 10 selected for the deposition of a material layer 4 onto the substrate 2 that includes silicon, and which is epitaxial with the substrate 2 and in this respect include a silicon-containing material layer precursor source 116. In further respect, it is also contemplated that the process fluid source 102 include one or more of a metal-containing material layer precursor source 118, a dopant-containing material layer precursor source 120, an etchant source 122, and diluent/carrier fluid source 124. Although shown and described herein as having certain elements and a specific arrangement, it is to be understood and appreciated that the process fluid source 102 may include additional elements and/or omit one or more element shown and described herein, as well as have a different arrangement, in other examples and remain within the scope of the present disclosure.

The silicon-containing material layer precursor source 116 is coupled to the chamber arrangement 104 by the process fluid supply conduit 110, includes a silicon-containing material layer precursor 16, and is configured to communicate the silicon-containing material layer precursor 16 to the chamber arrangement 104 via the process fluid 10. The silicon-containing material layer precursor source 116 may be coupled to the chamber arrangement 104 by a flow control device, such as a mass flow meter (MFM) device or a mass flow controller (MFC) device. In certain examples, the silicon-containing material layer precursor 16 may include a non-chlorinated silicon-containing material layer precursor. Examples of suitable non-chlorinated silicon-containing material layer precursor include silane (SiH₄), disilane (Si₂H₆), trisilane (Si₃H₈), and higher order non-chlorinated silicon-containing material layer precursors. In accordance with certain examples, the silicon-containing material layer precursor may include a chlorinated silicon-containing material layer precursor. Examples of suitable chlorinated material layer precursors include chlorosilane (H₃SiCl), dichlorosilane (H₂SiCl₂), trichlorosilane (HCl₃Si), and higher order chlorinated silicon-containing material layer precursors. It is also contemplated that the silicon-containing material layer precursor source 116 may be configured to communicate two or more of the aforementioned silicon-containing material layer precursors to the chamber arrangement 104, independent of one another or as a mixture including both, and remain within the scope of the present disclosure.

The metal-containing material layer precursor source 118 and the dopant-containing material layer precursor source 120 are similar to the silicon-containing material layer precursor source 116 and additionally include a metal-containing material layer precursor 18 and a dopant-containing material layer precursor 20, respectively. It is contemplated that the metal-containing material layer precursor 18 may include germanium and in this respect the metal-containing material layer precursor 18 may include a non-chlorinated germanium compound, such as germane (GeH₄), or a chlorinated germanium compound like gallium trichloride (GaCl₃). The dopant-containing material layer precursor 20 may include one or more of p-type dopant and/or an n-type dopant. For example, the dopant-containing material layer precursor 20 may include a p-type dopant such as boron (B) or indium (In) and/or an n-type dopant such as arsenic (As) or phosphorous (P). Non-limiting examples of suitable dopant-containing material layer precursors include diborane (B₂H₆) and arsine (AsH₄).

The etchant source 122 and the diluent/carrier fluid source 124 are also similar to the silicon-containing material layer precursor source 116 and in this respect may be coupled to the chamber arrangement 104 by the process fluid supply conduit 110, include an etchant 22 and a carrier/diluent fluid 24, respectively, and are configured to communicate a flow of the etchant 22 and the carrier/diluent fluid 24 to the chamber arrangement 104 via the process fluid 10, respectively. In certain examples the etchant source 122 may be configured to provide the etchant 22 to the chamber arrangement 104 as an independent fluid flow, such as for cleaning and/or purging the chamber arrangement 104, or intermixed with one or more of the aforementioned material layer precursors, such as in examples where selectivity is required in deposition and/or etch rates in processes where the substrate 2 has both exposed epitaxial surfaces and amorphous or polycrystalline surfaces. In accordance with certain examples, the diluent/carrier fluid source 124 may be configured to provide the carrier/diluent fluid 24 to the chamber arrangement 104 as an independent flow, such as for purging the chamber arrangement 104, as well intermixed with one or more of the aforementioned material layer precursors, such as a diluent fluid or a carrier fluid. It is also contemplated that the diluent/carrier fluid source 124 may be configured to intermix the carrier/diluent fluid 24 with the etchant 22 and remain within the scope of the present disclosure. Examples of suitable etchants include halide-containing compositions, such chlorine-containing compositions like hydrochloric (HCl) acid and chlorine (Cl₂) gas, as well as fluorine-containing compounds, such as hydrofluoric (HF) acid and fluorine (F₂) gas. Examples of suitable diluent/carrier fluids include hydrogen (H₂) gas and nitrogen (N₂) gas as well as noble gases like argon (Ar) gas, helium (He), and krypton (Kr) gas.

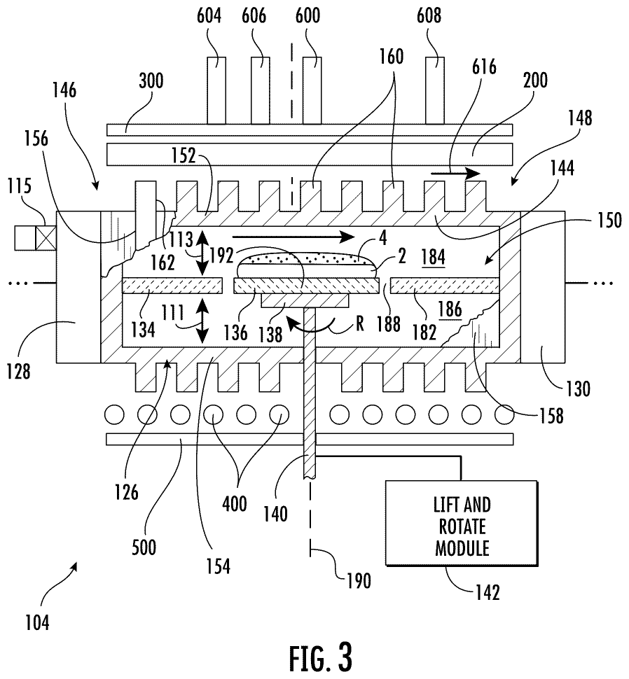

With reference to FIG. 3, the chamber arrangement 104 is shown according to an example of the disclosure. In the illustrated example the chamber arrangement 104 has a single-wafer crossflow architecture and includes a chamber body 126, an injection flange 128, an exhaust flange 130, an upper heater element array 200, an upper reflector 300, a lower heater element array 400, a lower reflector 500, and one or more non-contact temperature sensor 600. As shown and described herein the chamber arrangement 104 also includes a divider 134, a substrate support 136, a support member 138, a shaft member 140, and a lift and rotate module 142. Although shown and described herein as including certain elements and having a specific arrangement, it is to be understood and appreciated that the chamber arrangement 104 may include additional elements and/or exclude elements shown and described in the present disclosure, as well as have a different architecture, in other examples and remain within the scope of the present disclosure.

The chamber body 126 is formed from a ceramic material 144 and has an injection end 146 and a longitudinally opposite exhaust end 148. The injection flange 128 abuts the injection end 146 of the chamber body 126, is connected to the process fluid supply conduit 110 and fluidly couples the process fluid source 102 (shown in FIG. 1) to an interior 150 of the chamber body 126. The exhaust flange 130 abuts the exhaust end 148 of the chamber body 126, is connected to the exhaust conduit 112, and fluidly couples the interior 150 of the chamber body 126 to the exhaust source 106 (shown in FIG. 1). In certain examples the ceramic material 144 forming the chamber body 126 may include (or consist of or consist essentially of) a material transparent to electromagnetic radiation within an infrared waveband. For example, the ceramic material 144 may include (or consist of or consist essentially of) fused silica, quartz, or sapphire. In accordance with certain examples, the injection flange 128 may be as shown and described in U.S. Pat. No. 11,053,591 to Ma et al., issued on Jul. 6, 2021, and the exhaust flange 130 may be as shown and described in U.S. Pat. No. 11,168,395 to Sreeram et al., issued on Nov. 9, 2021, the contents of which are incorporated herein by reference in their entirety.

It is contemplated that the chamber body 126 have an upper wall 152, a lower wall 154, a first sidewall 156 and a second sidewall 158. The upper wall 152 may be generally planar in shape and extends longitudinally between the injection end 146 of the chamber body 126 and the exhaust end 148 of the chamber body 126. The lower wall 154 may also planar in shape, similarly extend longitudinally between the injection end 146 and the exhaust end 148 of the chamber body 126, and additionally be spaced apart from the upper wall 152 by the interior 150 of the chamber body 126. The first sidewall 156 extends longitudinally between the injection end 146 and the exhaust end 148 of the chamber body 126, couples the upper wall 152 of the chamber body 126 to the lower wall 154 of the chamber body 126, and may also be generally planar in shape. The second sidewall 158 is similar to the first sidewall 156, is additionally separated from the first sidewall 156 by the interior 150 of the chamber body 126, and may be substantially parallel to the first sidewall 156 of the chamber body 126. In certain examples of the present disclosure the walls (152-158) of the chamber body 126 may define a generally rectangular flow area within the chamber body 126 coupling the injection flange 128 and the exhaust flange 130 of the chamber arrangement 104. As will be appreciated by those of skill in the art in view of the present disclosure, the generally rectangular flow may promote laminar flow of the process fluid 10 within the interior 150 of chamber body 126, promoting tunability of cross-substrate properties of the material layer 4 using the injection flange 128. Although shown and described herein as being generally rectangular in shape, it is to be understood and appreciated that the chamber body 126 may have a different shape in other examples of the present disclosure, such as arcuate or dome-like, and remain within the scope of the present disclosure.

It is contemplated that the chamber body 126 have a one or more external rib 160. The one or more external rib 160 extends laterally about an exterior surface 162 of the chamber body 126. The one or more external rib 160 may be one of a plurality of external ribs 160 substantially parallel to one another, longitudinally space apart from one another between the injection end 146 and the exhaust end 148 of the chamber body 126, and extending continuously about the exterior surface 162 of the chamber body 126. It is further contemplated that the chamber body 126 be configured to maintain reduced pressure therein relative to the external environment 12 (shown in FIG. 1) outside of the chamber body 126. In this respect it is contemplated that pressure within the interior 150 of the chamber body 126 may be maintained at between about 0.1 Torr and about 760 Torr, or between about 0.1 Torr and about 700 Torr, or even between about 0.1 Torr and about 100 Torr during deposition of the material layer 4 onto the substrate 2. As will be appreciated by those of skill in the art in view of the present disclosure, this enables the process fluid 10 to flow between the injection end 146 and the exhaust end 148 of the chamber body 126 with a laminar flow pattern due to the generally rectangular shape of the interior of the chamber body 126 at low pressure, providing cross-substrate material layer property tunability using lateral mass flow adjustments. Although shown and described herein as having nine (9) external ribs, it is to be understood and appreciated that the chamber body 126 may have fewer or additional ribs in other examples and remain within scope of the present disclosure.

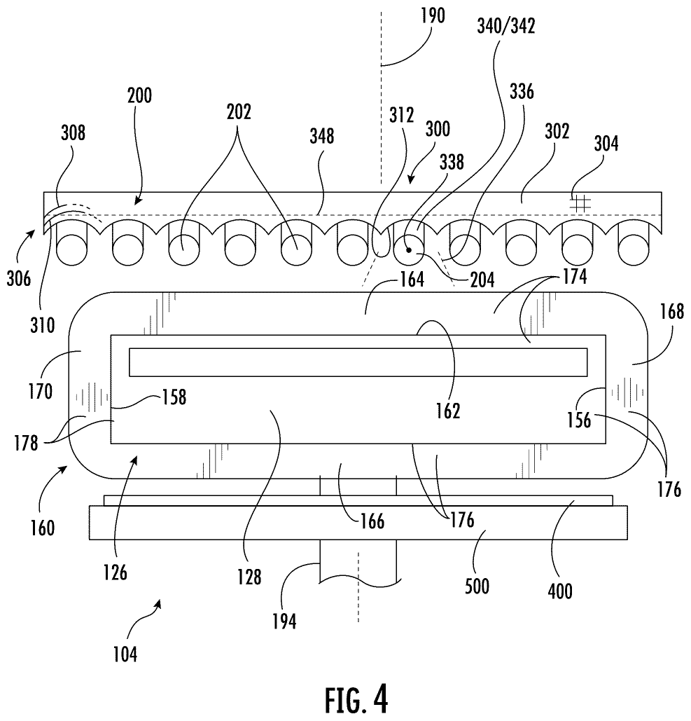

With reference to FIG. 4, it is contemplated that each of the one or more of the one or more external rib 160 have an upper rib portion 164, a lower rib portion 166, and a first side rib portion 168 and a second side rib portion 170. The upper rib portion 164 protrudes upwards (relative to gravity) from the exterior surface 162 of the chamber body 126 and in a direction opposite the interior 150 of chamber body 126. It is further contemplated that the upper rib portion 164 of the one or more external rib 160 be substantially orthogonal relative to the exterior surface 162 of the chamber body 126, that the upper rib portion 164 further be orthogonal relative to and either (or both) the first sidewall 156 and the second sidewall 158 of the chamber body 126, and that the upper rib portion 164 overlie the lower rib portion 166 of the one or more of the one or more external rib 160. The lower rib portion 166 in turn protrudes downwards from the exterior surface 162 of the lower wall 154 of the chamber body 126 and in a direction opposite the upper rib portion 164 of the one or more external rib 160, is also substantially orthogonal relative to the lower wall 154 of the chamber body 126, and may further be substantially orthogonal relative to the first sidewall 156 and the second sidewall 158 of the chamber body 126.

It is contemplated that the first side rib portion 168 of the one or more external rib 160 protrude laterally from the chamber body 126 in a direction opposite the interior 150 of the chamber body 126. The first side rib portion 168 may further be substantially orthogonal relative to either (or both) the first sidewall 156 and the second sidewall 158 of the chamber body 126, and extend vertically between the upper rib portion 164 and the lower rib portion 166 of the one or more external rib 160. It is further contemplated that the first side rib portion 168 couple the upper rib portion 164 of the one or more external rib 160 to the lower rib portion of the one or more external rib 160, for example at an welded joint, and that the second side rib portion 170 similar couple the upper rib portion 164 of the one or more external rib 160 to the lower rib portion 166 of the one or more external rib 160. In this respect it is contemplated that the second side rib portion 170 protrude laterally from the second sidewall 158 of the chamber body 126 and in a direction laterally opposite the first side rib portion 168 of the one or more external rib 160, additionally be substantially orthogonal relative to the second sidewall 158 of the chamber body 126, and additionally extend in parallel with the upper rib portion 164 and the lower rib portion 166 of the one or more external rib 160.

In certain examples of the present disclosure one or more of the walls 152-158 and rib portions 164-170 of the chamber body 126 may be formed from singular one-piece ceramic workpiece 174 using a subtractive manufacturing technique, for example by milling or boring. In this respect it is contemplated that the upper wall 152 (shown in FIG. 3) of the chamber body 126 and the upper rib portion 164 of the one or more of the one or more external rib 160 (shown in FIG. 3) may be formed from a singular one-piece ceramic workpiece 174 using a subtractive manufacturing technique. The lower wall 154 of the chamber body 126 (shown in FIG. 3) of the chamber body 126 and the lower rib portion 166 of the one or more of the one or more external rib 60 may be formed from a singular one-piece ceramic workpiece 176 using a subtractive manufacturing technique. In further respect, it is also contemplated that the first sidewall 156 (shown in FIG. 3) of the chamber body 126 and the first side rib portion 168 of the one or more of the one or more external rib 160, and/or the second sidewall 158 (shown in FIG. 3) of the chamber body 126 and the second side rib portion 170 of the one or more of the plurality of side rib portions 170 may be formed from a singular one-piece ceramic workpiece 176 and a singular one-piece ceramic workpiece 178, respectively, using a subtractive manufacturing technique. As will be appreciated by those of skill in the art in view of the present disclosure, forming one or more wall and rib portion extending therefrom can simplify fabrication of the chamber body 126, for example by limiting (or eliminating) the need to employ an additive technique such as welding to fabricate the chamber body 126. As will also be appreciated by those of skill in the art in view of the present disclosure, forming the upper wall 152 and the upper rib portion 164 using a subtractive technique may also limit geometric distortion otherwise imparted by certain additive manufacturing techniques, such as welding, improving tunability of cross-substrate properties of the material layer 4 (shown in FIG. 1) by eliminating the affect that such distortion may otherwise have upon electromagnetic radiation (and associated thermal variation) communicated into the interior 150 (shown in FIG. 3) by the upper heater element array 200.

With continuing reference to FIG. 3, it is contemplated that the divider 134 is formed from an opaque material 182 and seated within the interior 150 of the chamber body 126. It is also contemplated that the divider 134 divide the interior 150 of the chamber body 126 into an upper chamber 184 and a lower chamber 186, and that the divider 134 further define a divider aperture 188 therethrough fluidly coupling the upper chamber 184 to the lower chamber 186 of the chamber body 126. In certain examples of the present disclosure the opaque material 182 forming the divider 134 may a material opaque to electromagnetic radiation, for example to electromagnetic radiation in an infrared waveband. In accordance with certain examples, the opaque material 182 may be a ceramic material. Examples of suitable ceramic materials include silicon carbide, such as bulk silicon carbide, and other ceramics opaque to electromagnetic radiation in an infrared waveband.

The substrate support 136 is arranged within the interior 150 of the chamber body 126 and is configured to support the substrate 2 during deposition of the material layer 4 onto the substrate 2. In this respect it is contemplated that the substrate support 136 may be arranged at least in part within the divider aperture 188 and supported within the chamber body 126 for rotation R about a rotation axis 190. The substrate support 136 may further be formed from an opaque material 192 also opaque to electromagnetic radiation, for example to electromagnetic radiation in an infrared waveband. It is contemplated that a lower surface of the substrate support 136 and an interior surface of the lower wall 154 define therebetween a lower chamber height 111, that an upper surface of the substrate support 136 and an interior surface of the upper wall 152 of the chamber body 126 define an upper chamber height 113, and that the lower chamber height 111 may be smaller than the upper chamber height 113. As will be appreciated by those of skill in the art in view of the present disclosure, this can limit cost of operation of the chamber arrangement 104, for example by limiting the amount of purge fluid and/or etchant necessary for provision to the chamber body to discourage accretions from forming within mechanical clearances defined within the interior 150 of the chamber body 126. In certain examples of the present disclosure the opaque material 192 may include a carbonaceous material, such as a bulk carbonaceous material. Examples of suitable carbonaceous materials include graphite and pyrolytic carbon, with may further include a ceramic coating such as silicon carbide by way of non-limiting example. Examples of suitable substrate supports include those shown and described in U.S. Patent Application Publication No. 2022/0352006 A1, to Huang et al., filed on Apr. 27, 2022, the contents of which is incorporated herein by reference in its entirety.

The support member 138 and shaft member 140 couple the substrate support 136 to the lift and rotate module 142 to rotate the substrate support about the rotation axis 190. In this respect it is contemplated that the support member 138 be arranged within the lower chamber 186 of the chamber body 126 and along the rotation axis 190, be fixed in rotation R relative to the substrate support 136 about the rotation axis 190, and couple the substrate support 136 to the shaft member 140. The shaft member 140 in turn is fixed in rotation R relative to the support member 138 about the rotation axis 190, is arranged along the rotation axis 190, and extends through a passthrough defined within the lower wall 154 of the chamber body 126 and into the external environment 12 outside of the chamber arrangement 104. It is further contemplated that the shaft member 140 couple the substrate support 136 to the lift and rotate module 142 through the support member 138, that the shaft member 140 be arranged at least partially within a tube member 194 (shown in FIG. 4) affixed (e.g., by a welded joint) to the lower wall 154 of the chamber body 126, and that either (or both) the support member 138 and the shaft member 140 be formed from a transparent material 196, for example a material transparent to electromagnetic radiation in an infrared waveband. Examples of suitable transparent materials include certain ceramic materials, such as fused silica and quartz as well as sapphire.

The lift and rotate module 142 is configured to communicate rotation R to the substrate support 136 for rotation about the rotation axis 190 through the shaft member 140 and the support member 138. It is contemplated that the lift and rotate module 142 further be configured to seat and unseat the substrate 2 from the substrate support 136. In this respect it is contemplated that seating and unseating of the substrate 2 from the substrate support 136 may be accomplished using a plurality of lift pins slidably received within the substrate support 136 and a lift pin actuator extending about the shaft member 140, subsequent to loading and for unloading the substrate 2 into and out of the chamber body 126. Loading and unloading of the substrate 2 from the chamber body 126 may be accomplished using a gate valve 115 coupled to the injection flange 128 and a substrate transfer robot coupled to the injection flange 128 by the gate valve. Examples of lift pins and lift pin actuators include those shown and described in U.S. Patent Application Publication No. 2023/0116427 A1 to Su et al., filed on Oct. 7, 2022, the contents of which is incorporated herein by reference in its entirety.

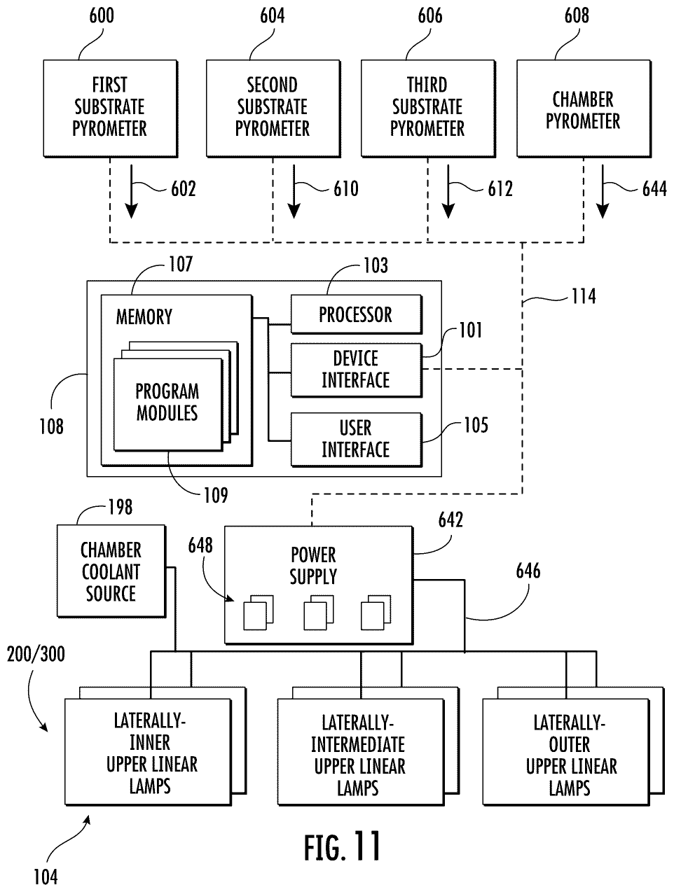

The one or more non-contact temperature sensor 600 is supported above the chamber body 126 and is configured to acquire a substrate temperature measurement 602 (shown in FIG. 11) of the substrate 2 and/or the material layer 4 directly and in real-time during deposition of the material layer 4 onto the substrate 2 using electromagnetic radiation emitted by the substrate 2 and/or the material layer 4. In this respect it is contemplated that the one or more non-contact temperature sensor 600 be supported above the chamber body 126 and fixed relative to the upper reflector 300. In further respect, it is also contemplated that the one or more non-contact temperature sensor 600 be disposed in communication with the controller 108, for example via the wired or wireless link 114, to provide the substrate temperature measurement 602 to the controller 108. The controller 108 may in turn be configured to control the upper heater element array 200 and/or the lower heater element array 400 using the substrate temperature measurement 602, the controller 108 thereby operably coupling the one or more non-contact temperature sensor 600 to the upper heater element array 200 and/or to the lower heater element array 400. As will be appreciated by those of skill in the art in view of the present disclosure, employment of one or more non-contact temperature sensor supported above the chamber body 126 may limit deviation of temperature of the substrate 2 and/or the material layer 4 during deposition onto the substrate 2, for example by enabling control (and adjustment) of temperature of the substrate 2 and/or the material layer 4 substantially in real-time with acquisition of temperature of the substrate 2 and/or the material layer 4 onto the substrate 2.

In the illustrated example the one or more non-contact temperature sensor 600 is a first substrate pyrometer 600 and the substrate temperature measurement is a first substrate temperature measurement 602, and the chamber arrangement 104 further includes a second substrate pyrometer 604, a third substrate pyrometer 606, and a chamber pyrometer 608. The second substrate pyrometer 604 is similar to the first substrate pyrometer 600 and additionally configured to acquire a second substrate temperature measurement 610 (shown in FIG. 11) of the substrate 2 and/or the material layer 4 during deposition onto the substrate 2 at a location radially outward of the first substrate temperature measurement 602. As will be appreciated by those of skill in the art in view of the present disclosure, controlling temperature of the substrate 2 and/or the material layer 4 using more than one substrate temperature measurement (e.g., two or more of the first substrate temperature measurement 602, the second substrate temperature measurement 610, and the third substrate temperature measurement 612) may improve temperature control of the substrate 2 and/or the material layer 4 during deposition onto the substrate, for example by averaging out cross-substrate temperature variation that could otherwise make a single substrate temperature measurement misrepresentative of the actual substrate temperature.

The third substrate pyrometer 606 may also be similar to the first substrate pyrometer 600 and additionally configured to acquire a third substrate temperature measurement 612 (shown in FIG. 11) of the substrate 2 and/or the material layer 4 during deposition onto the substrate 2 at a location radially intermediate (e.g., between) the locations from where first substrate temperature measurement 602 and the second substrate temperature measurement 610 are acquired by the first substrate pyrometer 600 and the second substrate pyrometer 604, respectively. As will also be appreciated by those of skill in the art in view of the present disclosure, controlling substrate temperature using temperature measurements acquired at different radial offsets relative to the rotation axis 190 (e.g., two or more of the first substrate temperature measurement 602, the second substrate temperature measurement 610, and the third substrate temperature measurement 612) may limit temperature variation of the substrate 2 and/or the material layer 4 during deposition of the material layer 4 onto the substrate 2, for example by enabling cross-substrate temperature differential control (e.g., center-to-edge differential) and/or cross-substrate temperature gradient control (e.g., center-to-edge second order or higher function) using individual ones heater elements included in the upper heater element array 200 and/or the lower heater element array 400.

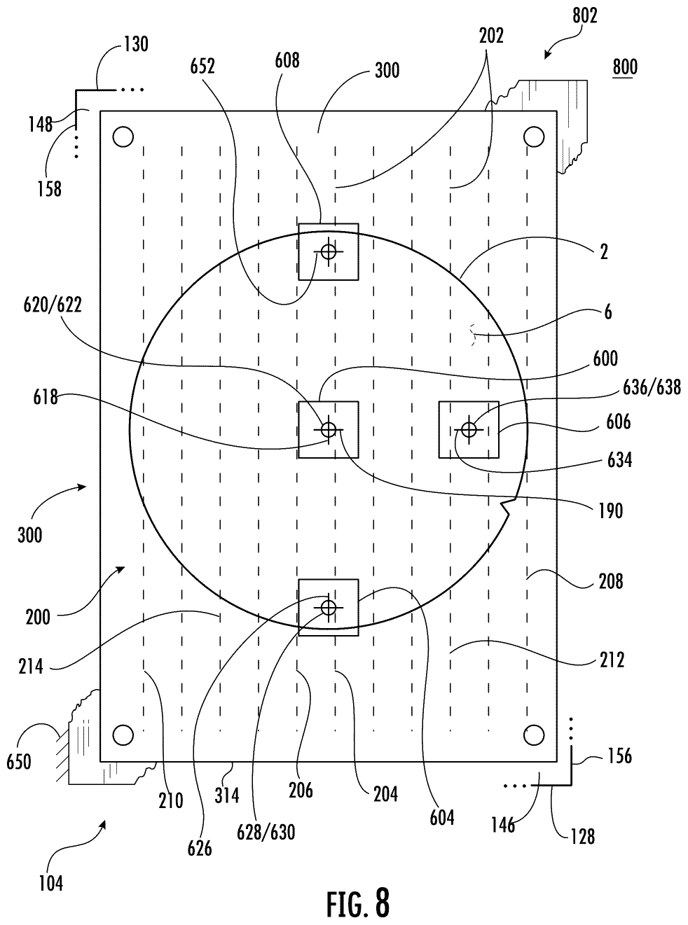

The chamber pyrometer 608 is similar to the first substrate pyrometer 600 and is additionally configured to acquire the chamber body temperature measurement 644 using electromagnetic radiation emitted by the chamber body 126, for example during deposition of the material layer 4 onto the substrate 2. It is contemplated that controller 108 operably couple the chamber pyrometer 608 to a coolant source, for example to throttle flow of a coolant 616 provided to the chamber body 126, to control temperature of the ceramic material 144 forming the chamber body 126. In certain examples of the present disclosure the chamber arrangement may include one or more coolant control feature 650 (shown in FIG. 8) to limit variation of flow and/or distribution of the coolant across the exterior surface 162 of the chamber body 126 and/or within optical paths of the aforementioned pyrometers, limiting (or eliminating) the need for chamber arrangement-specific coolant supply settings for the chamber arrangement 104 relative to other chamber arrangements, simplifying installation and/or maintenance of the chamber arrangement 104. In this respect one or more coolant control feature 650 may include a singular, one-piece reflector body; a single, one-piece reflector frame, and air gap closures and gasketing arranged about a periphery of the upper reflector 300.

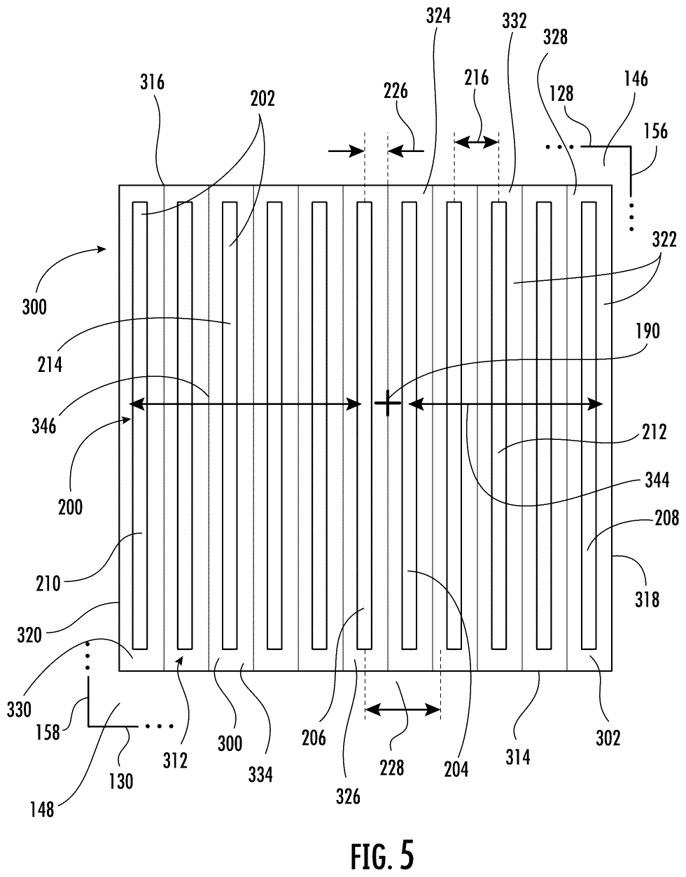

With reference to FIGS. 4 and 5, a portion of the chamber arrangement 104 including the upper heater element array 200 and upper reflector 300 are shown according to an example of the disclosure. In the illustrated example the upper heater element array 200 includes a plurality of filament-type upper linear lamps 202 supported vertically between the chamber body 126 and the upper reflector 300. It is contemplated that the plurality of filament-type upper linear lamps 202 be supported above the chamber body 126 and optically coupled to the interior 150 (shown in FIG. 3) of the chamber body 126 by the upper wall 152 (shown in FIG. 3) of the chamber body 126. It is also contemplated that the plurality of filament-type upper linear lamps 202 be configured to radiantly heat the substrate 2 (shown in FIG. 1) using electromagnetic radiation within an infrared waveband generated using electric current applied and individually tunable to individual ones of the plurality of filament-type upper linear lamps 202. It is further contemplated that the plurality of filament-type upper linear lamps 202 extend longitudinally between the injection end 146 and the exhaust end 148 of the chamber body 126, that the plurality of filament-type upper linear lamps 202 be angled (e.g., substantially orthogonal) relative to the one or more external rib 160 extending about the exterior surface 162 of the chamber body 126, and that the plurality of filament-type upper linear lamps 202 be laterally spaced apart from one another between the first sidewall 156 and the second sidewall 158 of chamber body 126.

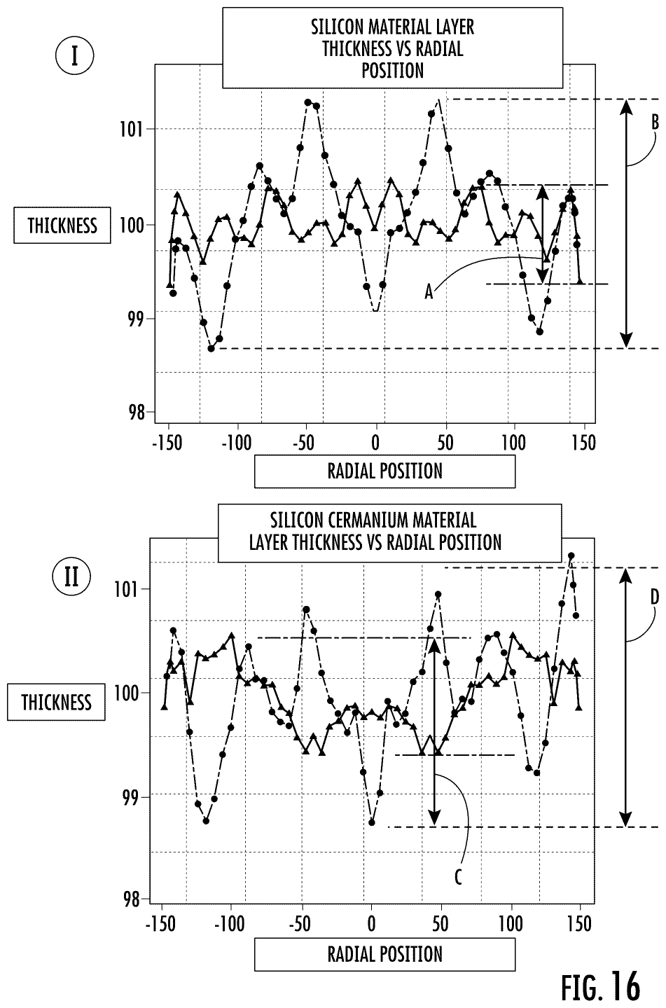

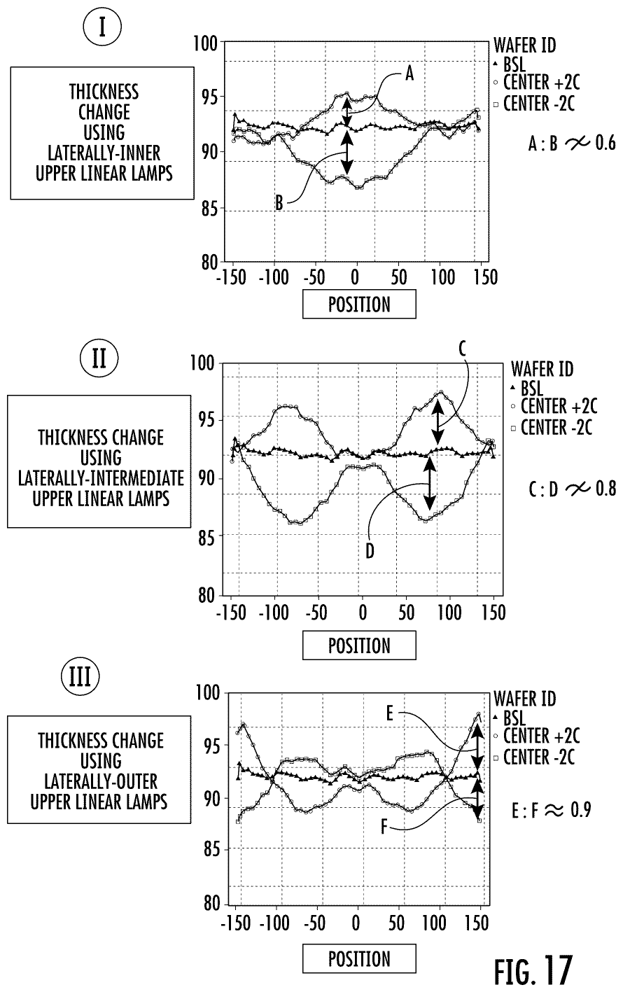

In certain examples of the disclosure one or more of the plurality of filament-type upper linear lamps 202 may be substantially parallel to either (or both) the first sidewall 156 and the second sidewall 158 of the chamber body 126. In accordance with certain examples, each of the plurality of filament-type upper linear lamps 202 may substantially parallel to one another and/or to either (or both) the first sidewall 156 and the second sidewall 158 of the chamber body 126. Advantageously, arranging the plurality of filament-type upper linear lamps 202 orthogonally relative to the one or more external rib 160 distributes the scattering effect that the one or more external rib 160 have on electromagnetic radiation communicated into the interior 150 (shown in FIG. 3) of the chamber body 126 relative to chamber arrangements having upper linear lamps extending in parallel to upper ribs of a chamber body. As will be appreciated by those of skill in the art in view of the present disclosure, this may limit (or eliminate) high order (e.g., ripple) cross-substrate temperature variation across the substrate 2 (shown in FIG. 1) otherwise potentially uncorrectable by individually tuning current applied to individual ones of the plurality of filament-type upper linear lamps 202. As will also be appreciated by those of skill in the art in view of the present disclosure, limiting (or eliminating) high order cross-substrate temperature variation may in turn limit cross-substrate variation within the material layer 4 (shown in FIG. 1) relative to material layers deposited in chambers having upper linear lamps extending in parallel with the upper ribs of the chamber body, as shown in FIGS. 16 and 17, increasing yield of semiconductor devices formed using the material layer 4.

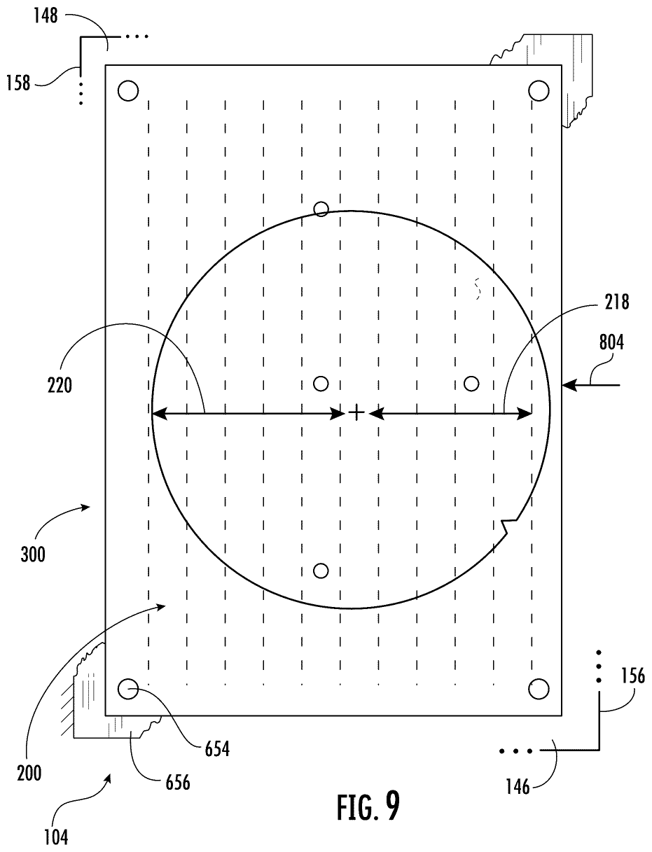

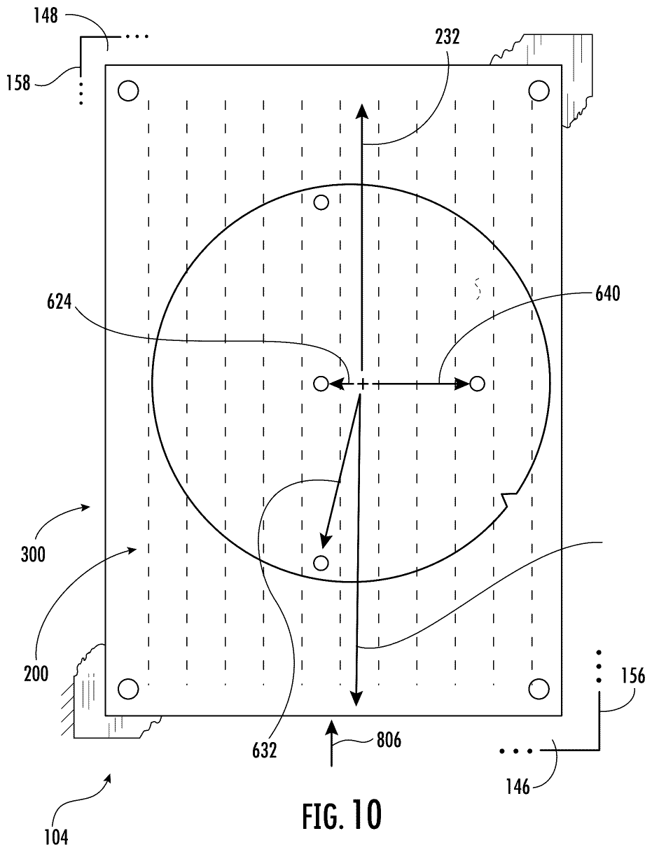

The upper heater element array 200 may be positioned asymmetrically above the chamber body 126. In this respect the upper heater element array 200 may be laterally offset above the chamber body 126 relative to rotation axis 190, for example such that the upper heater element array 200 is laterally separated from the rotation axis 190 by a first lateral spacing distance 218 (shown in FIG. 9) and further laterally separated from the rotation axis 190 by a second lateral spacing distance 220 (shown in FIG. 9), the second lateral spacing distance 220 greater than the first lateral spacing distance 218 in the illustrated example of the chamber arrangement 104. In further respect, the upper heater element array 200 may be longitudinally offset above the chamber body 126 relative to the rotation axis 190, for example such that the upper heater element array 200 is offset from the rotation axis 190 by a first longitudinal spacing distance 230 (shown in FIG. 10) and further offset from the rotation axis 190 by a second longitudinal spacing distance 232 (shown in FIG. 10) on a longitudinally opposite exhaust end of the upper heater element array 200, the first longitudinal spacing distance 230 being greater than the second longitudinal spacing distance 232 in the illustrated example. It is also contemplated that the upper heater element array 200 may be supported above the chamber body 126 such that the upper heater element array 200 is both laterally offset and longitudinally offset relative to the rotation axis 190 and remain within the scope of the present disclosure. Advantageously, arranging the plurality of filament-type upper linear lamps 202 asymmetrically above the chamber body 126 relative to the rotation axis 190 may limit (or eliminate) localized hot and cold spots on the substrate 2 (shown in FIG. 1) that could otherwise exist in chamber arrangements having upper linear lamps arranged symmetrically above the chamber body, limiting (or eliminating) cross-substrate temperature variation otherwise potentially associated with symmetric arrangement of the upper linear lamps. Limiting cross-substrate temperature variation across the substrate 2 in turn may limit cross-substrate variation within the material layer 4 (shown in FIG. 1), as shown in FIGS. 16 and 17, potentially improving yield of semiconductor devices formed using the material layer 4.

With continuing reference to FIGS. 4 and 5, the plurality of filament-type upper linear lamps 202 includes eleven (11) filament-type upper linear lamps in the illustrated example. In this respect the plurality of filament-type upper linear lamps 202 includes a laterally-inner first upper linear lamp 204 and a laterally-inner second upper linear lamp 206, a laterally-outer first upper linear lamp 208 and a laterally-outer second upper linear lamp 210, and a laterally-intermediate first upper linear lamp 212 and a laterally-intermediate second upper linear lamp 214. The laterally-inner first upper linear lamp 204 extends longitudinally between the injection end 146 and the exhaust end 148 of the chamber body 126, is substantially orthogonal relative to the one or more external rib 160 extending about the exterior surface 162 of the chamber body 126, and may be substantially parallel to either (or both) the first sidewall 156 and the second sidewall 158 of the chamber body 126. Examples of suitable filament-type linear lamps include those shown and described in U.S. Patent Application Publication No. 2005/0094989 A1, filed on Nov. 9, 2004, the contents of which are incorporated herein by reference in its entirety. Although shown and described herein as having eleven (11) filament-type upper linear lamps it is to be understood and appreciated that the upper heater element array may have fewer or additional filament-type upper linear lamps and remain within the scope of the present disclosure.

The laterally-inner second upper linear lamp 206 may be similar to the laterally-inner first upper linear lamp 204, may be additionally separated from the laterally-inner first upper linear lamp 204 by the rotation axis 190, and may further extend in parallel to the laterally-inner first upper linear lamp 204. The laterally-outer first upper linear lamp 208 and the laterally-outer second upper linear lamp 210 may also be similar to the laterally-inner first upper linear lamp 204, may additionally be separated from one another by the rotation axis 190, and may further be separated from the rotation axis by the laterally-inner first upper linear lamp 204 and the laterally-inner second upper linear lamp 206, respectively. The laterally-intermediate first upper linear lamp 212 and the laterally-intermediate second upper linear lamp 214 may be similar to the laterally-inner first upper linear lamp 204, may additionally be separated from one another by the rotation axis 190, and may further separate the laterally-inner first upper linear lamp 204 from the laterally-outer first upper linear lamp 208 and the laterally-inner second upper linear lamp 206 and the laterally-inner second upper linear lamp 206 from the laterally-outer second upper linear lamp 210, respectively. Advantageously, supporting the upper heater element array 200 above the chamber body 126 such that the plurality of filament-type upper linear lamps 202 are substantially orthogonal to the one or more external rib 160 limits the shadowing effect that the one or more external rib 160 may otherwise impart to heating of the substrate 2 (shown in FIG. 1) during deposition of the material layer 4 (shown in FIG. 1) onto the substrate 2, such as in chamber arrangements where upper linear lamps are arranged in parallel to external ribs of a chamber body, enabling cross-substrate temperature tuning using lamp power offsets. As will be appreciated by those of skill in the art in view of the present disclosure, limiting shadowing of the substrate 2 during deposition of the material layer 4 onto the substrate 2 in turn may limit variation imparted into the material layer 4 by the shadowing effect of the one or more external rib 160 relative to a chamber arrangement having upper linear lamps extending in parallel with the external ribs of the chamber body, as shown in FIGS. 16 and 17, potentially improving yield of semiconductor devices formed using the material layer 4 deposited onto the substrate 2.

With continuing reference to FIGS. 4 and 5, it is contemplated that the plurality of filament-type upper linear lamps 202 of the upper heater element array 200 may be symmetrically distributed laterally with respect to one another in certain examples of the present disclosure. In this respect it is contemplated that the each of the plurality of filament-type upper linear lamps 202 may be separated by a common spacing or pitch 216. In certain examples, the common spacing or pitch 216 may be such that pairs of the plurality of filament-type upper linear lamps 202 are separated from the rotation axis 190 by common radial offsets. In accordance with certain examples, the upper heater element array 200 may be laterally shifted, for example such that one of the laterally-inner first upper linear lamp 204 and the laterally-inner second upper linear lamp 206 are separated from the rotation axis 190 by less than about one-half the common spacing or pitch 216 of the plurality of filament-type upper linear lamps 202 included in the upper heater element array 200. For example, one of the laterally-inner first upper linear lamp 204 and the laterally-inner second upper linear lamp 206 may be separated from the rotation axis 190 by between about 1 millimeter and about one-half the common spacing or pitch 216 of the plurality of filament-type upper linear lamps 202 included in the upper heater element array 200.

In accordance with certain examples of the present disclosure, one or more laterally adjacent pairs of the plurality of filament-type upper linear lamps 202 may be separated from one another by a spacing differing from that defined between at least one pair of laterally adjacent upper linear lamps of the plurality of filament-type upper linear lamps 202. For example, a laterally adjacent pair of the plurality of filament-type upper linear lamps 202 may be laterally separated by a reduced upper lamp spacing distance 226 that is smaller than the common spacing or pitch 216 defined between another pair of laterally adjacent upper linear lamps of the plurality of filament-type upper linear lamps 202. Alternatively, a laterally adjacent pair of the plurality of filament-type upper linear lamps 202 may be laterally separated by an increased upper lamp spacing distance 228 that is greater than the common spacing or pitch 216 defined between another pair of laterally adjacent upper linear lamps of the plurality of filament-type upper linear lamps 202. Advantageously, examples of the upper heater element array 200 having the reduced upper lamp spacing distance 226 or the increased upper lamp spacing distance 228 positions each upper linear lamp of the plurality of filament-type upper linear lamps 202 at a different (e.g., unique) radial offset relative to the rotation axis 190, increasing the number of cross-substrate temperature adjustment locations, for example from six (6) to eleven (11) adjustment locations. As will be appreciated by those of skill in the art in view of the present disclosure, increasing the number of cross-substrate temperature adjustment locations may further limit cross-substrate temperature variation across the substrate 2 (shown in FIG. 1), further limiting variation potentially imparted into the material layer 4 (shown in FIG. 1) by the shadowing effect of the one or more external rib 160 relative to a chamber arrangement having upper linear lamps extending in parallel with the external ribs of the chamber body, for example by reducing cross-substrate non-uniformity by 30% relative to a chamber arrangement having symmetrically spaced upper linear lamps, potentially improving yield of semiconductor devices formed using the material layer 4 deposited onto the substrate 2.

In certain examples of the present disclosure the aforementioned increased number of upper heater element adjustment locations may be realized employing in an upper heater element array having the common spacing or pitch 216, limiting complexity of the chamber arrangement 104. In this respect it is contemplated that the upper heater element array 200 may be laterally offset relative to the rotation axis 190 toward one of the first sidewall 156 and the second sidewall 158 of the chamber body 126, for example such the laterally-inner first upper linear lamp 204 is offset from the rotation axis 190 by a laterally-inner first upper linear lamp offset 222 that is different than a laterally-inner second upper linear lamp offset 224. In certain examples the laterally-inner first upper linear lamp offset 222 may be less than the laterally-inner second upper linear lamp offset 224. For example, the laterally-inner first upper linear lamp offset 222 may be between about 5% and about 50% of the laterally-inner second upper linear lamp offset 224, or between about 5% and about 25% of the laterally-inner second upper linear lamp offset 224, or even between about 5% and about 10% of the laterally-inner second upper linear lamp offset 224. Advantageously, such examples may limit cross-substrate temperature variation in the material layer 4 (shown in FIG. 1) deposited onto the substrate 2 (shown in FIG. 1) to about 40% of that of an otherwise identical material layer deposited onto a substrate in a chamber arrangement having a symmetrical upper heater element array, as shown in FIGS. 16 and 17, while limiting modification of the reflector employed in the chamber arrangement for use on the chamber arrangement 104. As will be appreciated by those of skill in the art in view of the present disclosure, the laterally-inner second upper linear lamp offset 224 may be greater than the laterally-inner first upper linear lamp offset 222 and remain with the scope of the present disclosure.

As shown in FIG. 5, it is contemplated that the upper reflector 300 be supported above the upper wall 152 (shown in FIG. 3) of the chamber body 126 and at a location above the upper heater element array 200 such that the upper reflector 300 reflects electromagnetic radiation emitted by the plurality of filament-type upper linear lamps 202 in a direction opposite the chamber body 126 toward the chamber body 126. In this respect it is contemplated that the upper reflector body 302 be formed from an upper reflector bulk metallic material 304. In further respect, it is also contemplated that the upper reflector 300 include one or more reflective layer overlaying the upper reflector bulk metallic material 304. For example, the upper reflector 300 may include a first reflective layer 306 and a second reflective layer 308. The first reflective layer 306 may overlay the bulk metallic material 304 forming the upper reflector body 302. The second reflective layer 308 may overlay the first reflective layer 306. In certain examples the upper reflector bulk metallic material 304 may include (or consist of or consist essentially of) an aluminum-containing material, such as aluminum alloy like 6061 aluminum, or copper and/or zinc-containing material like brass or bronze. Advantageously, such materials may be resistant to zinc leaching in applications where the upper reflector material bulk metallic undergoes prolonged exposure to liquids, promoting longevity of the upper reflector 300 in applications wherein the upper reflector has a liquid coolant such as water or glycol-cooled through the upper reflector body 302.

It is contemplated that the first reflective layer 306 may have a first reflective layer reflectivity to electromagnetic radiation in an infrared waveband that is greater than a reflectivity of the bulk metallic material 304 forming the upper reflector body 302. It is also contemplated that the second reflective layer 308 may have a second reflective layer reflectivity that is substantially equivalent to the first reflective layer reflectivity. In certain examples the first reflective layer 306 may have a first reflective layer thickness, the second reflective layer 308 may have a second reflective layer thickness, and the second reflective layer thickness may be less than or equal to the first reflective layer thickness. In accordance with certain examples, the second reflective layer 308 may include (or consist of or consist essentially of) gold (Au), and the first reflective layer 306 may include (or consist of or consist essentially of) silver (Ag). Advantageously, forming the upper reflector 300 with the first reflective layer 306 and the second reflective layer 308 may limit cost of the upper reflector 300 relative to a reflector formed from a relatively thick reflective coating with substantially no reduction to reflectivity of the upper reflector 300 to electromagnetic radiation within an infrared waveband.

As shown in FIG. 5, it is contemplated that the upper reflector 300 may be generally rectangular in shape. In this respect the upper reflector 300 may be supported above the chamber body 126 such that relatively short edges of the upper reflector body 302 overlie (or longitudinally oppose) the injection end 146 and the exhaust end 148 of the chamber body 126, and that relatively long edges of the upper reflector 300 overlie (or laterally oppose) the first sidewall 156 and the second sidewall 158 of the chamber body 126. In illustrated example the upper reflector body 302 has an injection edge 314, an exhaust edge 316, a first lateral edge 318, and a second lateral edge 320. The injection edge 314 of the upper reflector body 302 is shorter than the first lateral edge 318 and the second lateral edge 320 of the upper reflector body 302, is substantially linear, extends between the first sidewall 156 and the second sidewall 158 of the chamber body 126, and overlies (or longitudinally opposes) the injection end 146 of the chamber body 126. The exhaust edge 316 of the upper reflector body 302 is longitudinally opposite the injection edge 314 of the upper reflector body 302, extends between the first sidewall 156 and the second sidewall 158 of the chamber body 126, and overlies (or longitudinally opposes) the exhaust end 148 of the chamber body 126. The first lateral edge 318 of the upper reflector body 302 couples the injection edge 314 of the upper reflector body 302 to the exhaust edge 316 of the upper reflector body 302, is laterally inward of the first sidewall 156 of the chamber body 126, and may be substantially parallel to the first sidewall 156 of the chamber body 126. The second lateral edge 320 of the upper reflector body 302 is similar to the first lateral edge 318 of the upper reflector body 302, may be substantially parallel to the first lateral edge 318 of the upper reflector body 302, and also couples the injection edge 314 to the exhaust edge 316 of the upper reflector body 302. In certain examples of the present disclosure either (or both) the first lateral edge 318 and the second lateral edge 320 may be orthogonal relative to the injection edge 314 of the upper reflector body 302. In accordance with certain examples, the second lateral edge 320 may be substantially orthogonal relative to either (or both) the injection edge 314 and the exhaust edge 316 of the upper reflector body 302.

In certain examples of the present disclosure the upper reflector body 302 may be monolithically formed as a singular one-piece upper reflector body 302. In this respect the upper reflector body 302 may extend contiguously and without interruption between the injection edge 314 and the exhaust edge 316. If further respect, the upper reflector body 302 may also extend contiguously and without interruption between the first lateral edge 318 and the second lateral edge 320 of the upper reflector body 302. As will be appreciated by those of skill in the art in view of the present disclosure, this can improve tunability of cross-substrate temperature variation of the substrate 2 (shown in FIG. 1), for example by limiting (or eliminating) joints between reflector segments that can other move relative to one another, for example responsive to change in shape associated with thermal cycling. In accordance with certain examples, the upper reflector 300 may be formed with two or more reflector segments, simplifying maintenance of the chamber arrangement 104, for example by limiting weight of the segments to within the one-man lift weight limit set forth in certain workplace safety regulations. Advantageously, examples having an upper reflector with the singular one-piece upper reflector body 302 may improve reliability of the chamber arrangement 104 (shown in FIG. 1), for example by limiting (or eliminating) heating variation potentially introduced due to one segment of a multi-segment reflector moving relative to another segment of the multi-segment reflector. The singular one-piece upper reflector body 302 may also simplify matching the chamber arrangement 104 to another chamber arrangement due to aforementioned reduction in temperature variation potentially otherwise imparted by multi-segment reflectors.

It is contemplated that the upper reflector 300 define a plurality of arcuate recesses 322 in the reflective surface 312 and opposing the upper wall 152 (shown in FIG. 3) of the chamber body 126. In the illustrated example the upper reflector 300 defines a laterally-inner first arcuate recess 324 and a laterally-inner second arcuate recess 326, a laterally-outer first arcuate recess 328 and a laterally-outer second arcuate recess 330, and a laterally-intermediate first arcuate recess 332 and a laterally-intermediate second arcuate recess 334 within the reflective surface 312 of the upper reflector 300. The laterally-inner first arcuate recess 324 extends between the injection edge 314 and the exhaust edge 316 of the upper reflector body 302. The laterally-inner first arcuate recess 324 may further couple the injection edge 314 of the upper reflector body 302 to the exhaust edge 316 of the upper reflector body 302. It also is contemplated that the laterally-inner first arcuate recess 324 define longitudinally therealong an upper recess profile 336. The upper recess profile 336 may be substantially parabolic in shape, the upper recess profile 336 in turn having an upper recess focus 338 offset from the reflective surface 312 and within the laterally-inner first arcuate recess 324. In certain examples of the present disclosure the upper recess profile 336 may extend continuously and without interruption between the injection edge 314 of the upper reflector body 302 and the exhaust edge 316 of the upper reflector body 302, the upper recess focus 338 thereby defining a focus line including the upper recess focus 338 extending longitudinally along at a location offset from and parallel to the reflective surface 312 of the upper reflector 300.

In certain examples of the disclosure substantially all of the reflective surface 312 opposing the chamber body 3126 may be occupied by the plurality of arcuate recesses 322, the upper reflector being fully parabolic in such examples. In accordance with certain examples of the present disclosure the upper reflector 300 may further have a planar surface portion 348 (shown in FIG. 4). The planar surface portion 348 may extend longitudinally between the injection edge 314 and an exhaust edge 316 of the upper reflector 300 in such examples. The planar surface portion 348 may also laterally separate the laterally-outer first arcuate recess 328 from the laterally-outer second arcuate recess 330 in such examples.

In accordance with certain examples, the injection edge 314 of the upper reflector 300 may be separated from the rotation axis 190 by an injection edge offset 350 and the longitudinally opposite exhaust edge 316 separated from the rotation axis by an exhaust edge offset 352, One of the injection edge offset 352 and the exhaust edge offset 354 may be greater than the other of the injection edge offset 350 and the exhaust edge offset 352. The differential between the inject edge offset 350 and the exhaust edge 352 may be substantially equivalent to a longitudinal component of change in position of a second substrate pyrometer aperture 628 (shown in FIG. 8) when the upper reflector 300 is laterally shifted 804 (shown in FIG. 9) to introduce an irregular spacing of the plurality of filament-type linear lamps 202 between the first sidewall 156 and the second sidewall 158 of the chamber body 126 relative to the rotation axis 190.

It is contemplated that the laterally-inner first upper linear lamp 204 depend from the upper reflector 300, be fixed relative to the upper reflector 300 by an injection end standoff 340 and a longitudinally opposite exhaust end standoff 342, and the that the injection end standoff 340 and the longitudinally opposite exhaust end standoff 342 in turn be sized and dimensioned such that the laterally-inner first upper linear lamp 204 overlaps the upper recess focus 338 along a longitudinal length of the laterally-inner first upper linear lamp 204. It is further contemplated that either (or both) the injection end standoff 340 and the longitudinally opposite exhaust end standoff 342 carry source and return leads connected to a linear filament arranged within the laterally-inner first upper linear lamp 204, and that the injection end standoff 340 and the longitudinally opposite exhaust end standoff 342 be sized and dimensioned to position the linear filament relative to the upper recess focus 338 to uniformly distribute electromagnetic radiation emitted by the laterally-inner first upper linear lamp 204 uniformly within the interior 150 (shown in FIG. 3) of the chamber body 126 including a surface portion of substrate 2 (shown in FIG. 1).

In certain examples the filament within the laterally-inner first upper linear lamp 204 may be centered substantially about the upper recess focus 338. In accordance with certain examples, the filament of the laterally-inner first upper linear lamp 204 may be centered about a point between the reflective surface 312 and the upper recess focus 338. It is contemplated that, in accordance with certain examples of the present disclosure, the filament of the laterally-inner first upper linear lamp 204 may be centered about a point separated from the reflective surface 312 by the upper recess focus 338. Advantageously, centering the filament substantially about the upper recess focus 338 may limit intensity of electromagnetic radiation reflected by the laterally-inner first arcuate recess 324 along axes oblique relative to the rotation axis 190. Limiting intensity of electromagnetic radiation reflected by the laterally-inner first arcuate recess 324 along axes oblique relative to the rotation axis 190 in turn reduces cross-substrate temperature variation along the substrate 2 (shown in FIG. 1) otherwise associated with such reflected electromagnetic radiation. Advantageously, this may limit cross-substrate variation within the material layer 4 (shown in FIG. 1) otherwise associated electromagnetic radiation reflected along axes oblique relative to the rotation axis 190.

It is contemplated that the laterally-inner second arcuate recess 326 may be similar to the laterally-inner first arcuate recess 324 and additionally separated from the laterally-inner first arcuate recess 324 by the rotation axis 190. The laterally-inner second arcuate recess 326 may further extend in parallel relative to the laterally-inner first arcuate recess 324 and be laterally adjacent to the laterally-inner first arcuate recess 324, for example with no arcuate recess therebetween. The laterally-outer first arcuate recess 328 and the laterally-outer second arcuate recess 330 may also be similar to the laterally-inner first arcuate recess 324, additionally be separated from one another by the laterally-inner first arcuate recess 324 and the rotation axis 190, and further extend in parallel with the laterally-inner first arcuate recess 324. It is contemplated that the laterally-outer first arcuate recess 328 bound the first lateral edge 318 of the upper reflector body 302 and be laterally separated from the rotation axis 190 by a first arcuate recess lateral offset 344, that the laterally-outer second arcuate recess 330 bound the second lateral edge 320 and be laterally separated from the rotation axis 190 by a second arcuate recess lateral offset 346, and that the second arcuate recess lateral offset 346 be greater than or less than the first arcuate recess lateral offset 344 such that the upper reflector 300 is asymmetric relative to the rotation axis 190. Advantageously, in examples wherein each of the plurality of filament-type upper linear lamps 202 are fixed relative to the upper reflector 300 within individual ones of the plurality of arcuate recesses 322, the plurality of filament-type upper linear lamps 202 may be irregularly (e.g., asymmetrically relative to the rotation axis) spaced relatively to the rotation axis 190. Advantageously, this may increase tunability by providing as many as eleven (11) radial locations across the substrate 2 whereat the cross-substrate temperature profile of the substrate 2 may be adjusted by throttling power applied to individual ones of the plurality of filament-type upper linear lamps 202.

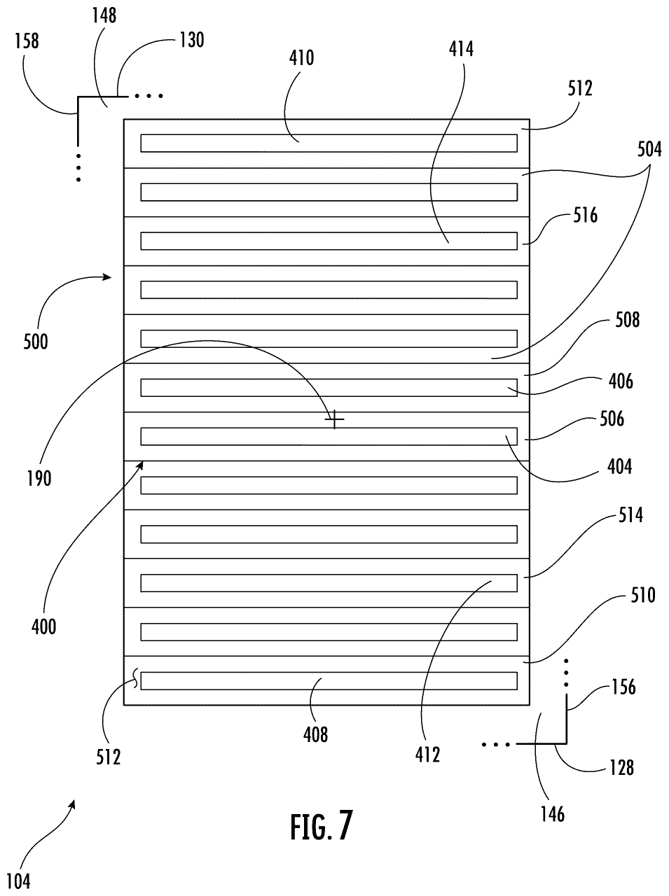

The laterally-intermediate first arcuate recess 332 and the laterally-intermediate second arcuate recess 334 may further be similar to the laterally-inner first arcuate recess 324 and additionally extend in parallel with the laterally-inner first arcuate recess 324. The laterally-intermediate first arcuate recess 332 may further be laterally intermediate the laterally-inner first arcuate recess 324 and the laterally-outer first arcuate recess 328, and the laterally-intermediate second arcuate recess 334 may further be laterally intermediate the laterally-inner second arcuate recess 326 and the laterally-outer second arcuate recess 330. In this respect it is contemplated that the laterally-intermediate first arcuate recess 332 and the laterally-intermediate second arcuate recess 334 separate the laterally-outer first arcuate recess 328 from the laterally-outer second arcuate recess 330. In certain examples the present disclosure the upper reflector may define a first substrate pyrometer aperture 620 (shown in FIG. 8) and a second substrate pyrometer aperture 628 (shown in FIG. 8). In accordance with certain examples, the lower reflector 500 may define therein a longitudinally-inner first arcuate recess 506 (shown in FIG. 7) and a longitudinally-outer first arcuate recess 510 (shown in FIG. 7), the longitudinally-inner first arcuate recess 506 may be longitudinally separated from the rotation axis by the first substrate pyrometer aperture 620, and the longitudinally-outer first arcuate recess 510 may be longitudinally separated from the longitudinally-inner first arcuate recess 506 by the second substrate pyrometer aperture 628. It is further contemplated that the upper reflector 300 may define therethrough a third substrate pyrometer aperture 636, and that the laterally-intermediate first arcuate recess 332 may separate may laterally separate the third substrate pyrometer aperture 636 from the laterally-inner first arcuate recess 324.

The plurality of the arcuate recesses 322 defined within the reflective surface 312 of the upper reflector 300 may correspond in number and arrangement to the plurality of filament-type upper linear lamps 202. In this respect the laterally-outer first upper linear lamp 208 may depend from the upper reflector 300 at a location whereat the laterally-outer first arcuate recess 328 overlays the laterally-outer first upper linear lamp 208, the laterally-outer second upper linear lamp 210 may depend from the upper reflector 300 at a location whereat the laterally-outer second arcuate recess 330 overlays the laterally-outer second upper linear lamp 210, the laterally-intermediate first upper linear lamp 212 may depend from the upper reflector 300 at a location whereat the laterally-intermediate first arcuate recess 332 overlays the laterally-intermediate first upper linear lamp 212, and the laterally-intermediate second upper linear lamp 214 may depend from the upper reflector 300 at a location whereat the laterally-intermediate second arcuate recess 334 overlays the laterally-intermediate second upper linear lamp 214.

It is contemplated that the laterally-outer first upper linear lamp 208 and the laterally-outer second upper linear lamp 210 may be vertically spaced from the laterally-outer first arcuate recess 328 and laterally-outer second arcuate recess 330 substantially equivalent to that of the laterally-inner first upper linear lamp 204. It is also contemplated that the laterally-intermediate first upper linear lamp 212 and the laterally-intermediate second upper linear lamp 214 also be vertically spaced from the laterally-intermediate first arcuate recess 332 and laterally-intermediate second arcuate recess 334 substantially equivalent to that of the laterally-inner first upper linear lamp 204. Advantageously, such spacing may further limit intensity of electromagnetic radiation reflected by the reflective surface 312 along axes oblique relative to the rotation axis 190 such that cross-substrate material layer variation within the material layer 4 (shown in FIG. 1) is on the order of about 40% that of cross-substrate material layer variation of an otherwise identical material layer (e.g., as shown in FIG. 16) deposited in a chamber arrangement without the aforementioned upper linear lamp spacing between the upper reflector and chamber body. In the illustrated example the upper reflector 300 is fully parabolic and in this respect an entirety of the reflective surface 312 is occupied by eleven (11) arcuate recesses defined within the reflective surface 312 of the upper reflector 300. As will be appreciated by those of skill in the art in view of the present disclosure, the upper reflector 300 may define fewer or additional arcuate recesses in other examples and remain within the scope of the present disclosure.

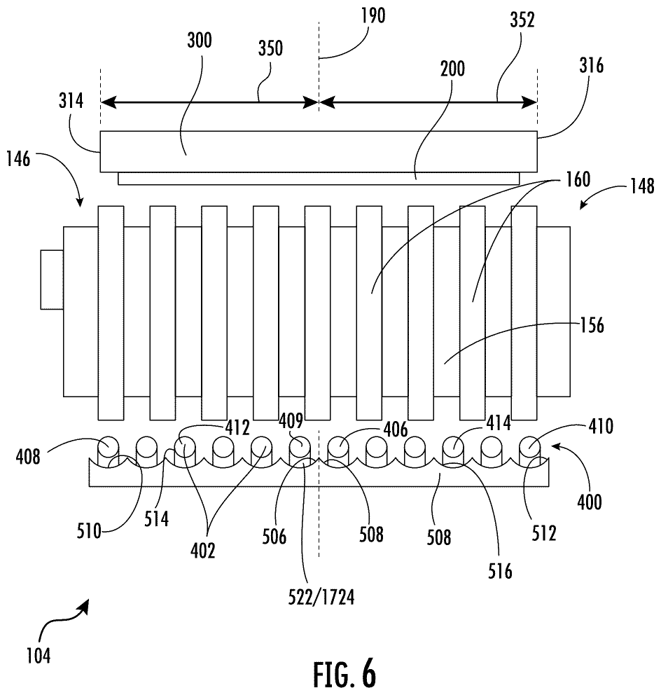

Referring to FIGS. 6 and 7, a portion of the chamber arrangement 104 including the lower heater element array 400 and the lower reflector 500 is shown. The lower heater element array 400 is similar to the upper heater element array 200, is additionally supported below (relative to gravity) the chamber body 126 and separates the lower reflector 500 from the chamber body 126. It is contemplated that the lower heater element array 400 include a plurality of filament-type lower linear lamps 402. The plurality of filament-type lower linear lamps 402 may similar to the plurality of filament-type upper linear lamps 202 and may additionally be arranged orthogonally relative to the plurality of filament-type upper linear lamps 202, and may be greater than the plurality of filament-type upper linear lamps 202. It is contemplated that the plurality of filament-type upper linear lamps 202 may be laterally spaced apart from one another between the injection end 146 and the exhaust end 148 of the chamber body 126, and that individual ones of the plurality of filament-type lower linear lamps 402 may be substantially parallel to the one or more external rib 160 of the chamber body 126. Although shown and described herein as including the plurality of filament-type lower linear lamps 402, it is to be understood and appreciated that the lower heater element array 400 may additionally include one or more spot-type lamp and remain within the scope of the present disclosure.

In the illustrated example the plurality of filament-type lower linear lamps 402 includes a longitudinally-inner first lower linear lamp 404 and a longitudinally-inner second lower linear lamp 406, a longitudinally-outer first lower linear lamp 408 and a longitudinally-outer second lower linear lamp 410, and a longitudinally-intermediate first lower linear lamp 412 and a longitudinally-intermediate second lower linear lamp 414. The longitudinally-inner first lower linear lamp 404 and the longitudinally-inner second lower linear lamp 406 are longitudinally adjacent to one another with no lower filament-type lower linear lamp therebetween, and are separated from one another by the rotation axis 190. It is contemplated that both the longitudinally-inner first lower linear lamp 404 and the longitudinally-inner second lower linear lamp 406 may further be substantially parallel to the one or more external rib 160 extending about the exterior surface 162 of the chamber body 126. In certain examples, the longitudinally-inner first lower linear lamp 404 and the longitudinally-inner second lower linear lamp 406 may be longitudinally spaced from the rotation axis 190 by equivalent distances. In accordance with certain examples, the longitudinally-inner first lower linear lamp 404 and the longitudinally-inner second lower linear lamp 406 may be separated from the rotation axis 190 by different values and remain within the scope of the present disclosure.

The longitudinally-outer first lower linear lamp 408 and the longitudinally-outer second lower linear lamp 410 are similar to the longitudinally-inner first lower linear lamp 404 and the longitudinally-inner second lower linear lamp 406 and are additionally longitudinally separated from the rotation axis 190 by the longitudinally-inner first lower linear lamp 404 and the longitudinally-inner second lower linear lamp 406. The longitudinally-intermediate first lower linear lamp 412 and the longitudinally-intermediate second lower linear lamp 414 are also similar to the longitudinally-inner first lower linear lamp 404 and the longitudinally-inner second lower linear lamp 406, are also longitudinally separated from the rotation axis 190 by the longitudinally-inner first lower linear lamp 404 and the longitudinally-inner second lower linear lamp 406, and further longitudinally separate the longitudinally-inner first lower linear lamp 404 and the longitudinally-inner second lower linear lamp 406 from the longitudinally-outer first lower linear lamp 408 and the longitudinally-outer second lower linear lamp 410, respectively. In the illustrated example the plurality of filament-type lower linear lamps 402 includes twelve (12) lower filament-type lamps. As will be appreciated by those of skill in the art in view of the present disclosure, the plurality of filament-type lower linear lamps 402 may include fewer or additional filament-type lower linear lamps and remain within the scope of the present disclosure.

The lower reflector 500 is similar to the upper reflector 300 and is additionally supported below the chamber body 126 at a location where the lower heater element array 400 separates the lower reflector 500 from the chamber body 126. It is contemplated that the lower reflector 500 further have a reflective surface 502 opposing the chamber body 126 and configured to reflect electromagnetic radiation emitted by the lower heater element array 400 in a direction away from the chamber body 126 toward the chamber body 126. It further contemplated that the lower reflector 500 define a plurality of arcuate recesses 504 within the reflective surface 502, which may correspond in number and arrangement to the plurality of filament-type lower linear lamps 402 included in the lower heater element array 400, and which may be substantially orthogonal relative to the one or more external rib 160 of the chamber body 126 and/or the plurality of arcuate recesses 322 defined in the reflective surface 312 of the upper reflector 300. In this respect it is contemplated that the plurality of arcuate recesses 504 include a longitudinally-inner first arcuate recess 506 and a longitudinally-inner second arcuate recess 508, a longitudinally-outer first arcuate recess 510 and a longitudinally-outer second arcuate recess 512, and a longitudinally-intermediate first arcuate recess 514 and a longitudinally-intermediate second arcuate recess 516 each defined within the reflective surface 502 and opposing the chamber body 126. In certain examples the plurality of arcuate recesses 504 defined within the lower reflector 500 may be greater than the plurality of arcuate recesses 322 defined within the upper reflector 300. In accordance with certain examples, the plurality of arcuate recesses 504 defined within the lower reflector 500 may be substantially orthogonal relative to the plurality of arcuate recesses 322 defined within the upper reflector 300.

The longitudinally-inner first arcuate recess 506 and the longitudinally-inner second arcuate recess 508 are longitudinally adjacent (e.g., with no arcuate recess therebetween) and are separated from one another by the rotation axis 190, extend longitudinally between a first lateral edge 518 and a second lateral edge 520 of the lower reflector 500, and may extend continuously and without interruption between the first lateral edge 518 and the second lateral edge 520. It is contemplated that the longitudinally-inner first lower linear lamp 404 be supported above and at least partially within the longitudinally-inner first arcuate recess 506, for example on a first lateral standoff 522 and a laterally opposite second lateral standoff 524, and that the longitudinally-inner first lower linear lamp 404 be substantially parallel to the longitudinally-inner first arcuate recess 506. It is further contemplated that the longitudinally-inner second lower linear lamp 406 be supported above and at least partially within the longitudinally-inner second arcuate recess 508, that the longitudinally-inner second lower linear lamp 406 further be supported by a first lateral standoff and a laterally opposite second lateral standoff separating the longitudinally-inner second lower linear lamp 406 from the lower reflector 500.

The longitudinally-outer first arcuate recess 510 and the longitudinally-outer second arcuate recess 512 are similar to the longitudinally-inner first arcuate recess 506 and the longitudinally-inner second arcuate recess 508, and are additionally longitudinally separated from the rotation axis 190 by the longitudinally-inner first arcuate recess 506 and the longitudinally-inner second arcuate recess 508. It is contemplated that the longitudinally-outer first lower linear lamp 408 be supported above the longitudinally-outer first arcuate recess 510 such that the longitudinally-outer first lower linear lamp 408 is arranged at least partially within the longitudinally-outer first arcuate recess 510, and that the longitudinally-outer second lower linear lamp 410 be supported above the longitudinally-outer second arcuate recess 512 such that longitudinally-outer second lower linear lamp 410 is arranged at least partially within the longitudinally-outer second arcuate recess 512. It is further contemplated that the longitudinally-intermediate first arcuate recess 514 separate the longitudinally-outer first arcuate recess 510 from the longitudinally-inner first arcuate recess 506, that the longitudinally-intermediate second arcuate recess 516 separate the longitudinally-outer second arcuate recess 512 from the longitudinally-inner second arcuate recess 508, and that the longitudinally-intermediate first lower linear lamp 412 be supported above and at least partially within the longitudinally-intermediate first arcuate recess 514 and the longitudinally-intermediate second lower linear lamp 414 be supported above and at least partially within the longitudinally-intermediate second arcuate recess 516. In the illustrated example the lower reflector 500 is fully parabolic and in this respect an entirety of the reflective surface 502 is occupied by twelve (12) arcuate recesses 504 defined within the reflective surface 502, each arcuate recess 504 in turn corresponding to one of twelve (12) filament-type lower linear lamps 402. As will be appreciated by those of skill in the art in view of the present disclosure, the lower reflector 500 may have fewer or additional arcuate recesses that shown and described herein and remain within the scope of the present disclosure.

With reference to FIG. 8 and continuing reference to FIG. 3, a portion the chamber arrangement 104 including the upper heater element array 200 and the upper reflector 300 is shown according to an example of the disclosure. It is contemplated that the chamber arrangement 104 include one or more pyrometers. In the illustrated example the chamber arrangement 104 includes a first substrate pyrometer 600 arranged along a first substrate pyrometer optical axis 618, a second substrate pyrometer 604 arranged along a second substrate pyrometer optical axis 626, a third substrate pyrometer 606 arranged along a third substrate pyrometer optical axis 634, and a chamber pyrometer 608 arranged along a chamber pyrometer optical axis 652. The first substrate pyrometer optical axis 618 extend from the first substrate pyrometer 600 and through a first substrate pyrometer aperture 620 defined in the upper reflector 300, between the laterally-inner first upper linear lamp 204 and the laterally-intermediate first upper linear lamp 212 of the upper heater element array 200, and through the upper wall 152 of the chamber body 126 such that the first substrate pyrometer optical axis 618 intersects the substrate support 136 within the chamber body 126 and the substrate 2 when seated on the substrate support 136. The first substrate pyrometer optical axis 618 may additionally extend between the longitudinally-inner first lower linear lamp 404 (shown in FIG. 6) and the longitudinally-inner second lower linear lamp 406 (shown in FIG. 6). It is contemplated that the first substrate pyrometer 600 have a first substrate pyrometer field of view 622 including a radially inner portion of the upper surface 6 of the substrate 2, and/or the material layer 4 during deposition thereon, located along the first substrate pyrometer optical axis 618 when the substrate 2 is seated on the substrate support 136.

The first substrate pyrometer optical axis 618 may intersect the substrate support 132 (and the substrate 2 when the substrate 2 is seated on the substrate support 136) at a first substrate pyrometer radial offset 624 (shown in FIG. 10). The first substrate pyrometer optical axis 618 may also be substantially parallel to the rotation axis 190 at least within the interior 150 of the chamber body 126, the first substrate pyrometer optical axis 618 substantially orthogonal relative to the upper surface 6 of the substrate 2 when the substrate 2 is seated on the substrate support 136. It is contemplated that the first substrate pyrometer radial offset 624 may between about 1 millimeter and about 50 millimeters, or between about 1 millimeter and about 40 millimeters, or even between about 5 millimeters and about 25 millimeters. As will be appreciated by those of skill in the art in view of the present disclosure, first substrate pyrometer radial offsets within these ranges can simplify controlling temperature of the substrate 2 and/or the material layer 4 during deposition of the material layer 4 onto the substrate 2 using electromagnetic radiation emitted by the substrate 2 and/or the material layer 4 from within the first substrate pyrometer field of view 622, for example by limiting (or eliminating) the need to otherwise compensate for crosstalk between upper linear lamps laterally outward of the laterally-inner first upper linear lamp 204 and the laterally-inner second upper linear lamp 206, for example when power to such upper linear lamps is independently throttled.

The second substrate pyrometer 604 is similar to the first substrate pyrometer 600 and in this respect the second substrate pyrometer optical axis 626 extends from the second substrate pyrometer 604 and through a second substrate pyrometer aperture 628 defined in the upper reflector 300, between the laterally-inner first upper linear lamp 204 and the laterally-intermediate first upper linear lamp 212 of the upper heater element array 200, and through the upper wall 152 of the chamber body 126 to intersect the substrate support 136 within the chamber body 126 and the substrate 2 when seated on the substrate support 136. The second substrate pyrometer optical axis 626 may further extend between the longitudinally-outer first lower linear lamp 408 (shown in FIG. 6) and the longitudinally-intermediate first lower linear lamp 412 (shown in FIG. 6). It is contemplated that the second substrate pyrometer 604 have a second substrate pyrometer field of view 630. It is also contemplated that the second substrate pyrometer field of view 630 in turn include a radially-outer portion of the upper surface 6 of the substrate 2, and/or the material layer 4 during deposition thereon, located along the second substrate pyrometer optical axis 626 and radially outward for the first substrate pyrometer field of view 622 when the substrate 2 is seated on the substrate support 136.

It is contemplated that the second substrate pyrometer optical axis 626 intersect the substrate support 136, and the substrate 2 when seated on the substrate support 136, at a second substrate pyrometer radial offset 632. The second substrate pyrometer optical axis 626 may also be substantially parallel to the rotation axis 190 at least within the interior 150 of the chamber body 126. The second substrate pyrometer optical axis 626 may further be substantially orthogonal relative to the upper surface 6 of the substrate 2 when seated on the substrate support 136. It is contemplated that the second substrate pyrometer radial offset 632 may between about 100 millimeters and about 150 millimeters, or between about 120 millimeter and about 150 millimeters, or even between about 130 millimeters and about 140 millimeters. As will be appreciated by those of skill in the art in view of the present disclosure, second substrate pyrometer radial offsets within these ranges can simplify controlling temperature of the substrate 2 and/or the material layer 4 during deposition of the material layer 4 onto the substrate 2 using electromagnetic radiation emitted by the substrate 2 and/or the material layer 4 from within the second substrate pyrometer field of view 630, for example by enabling a common offset to be employed by the controller 108 to compensate the first substrate temperature measurement 602 (shown in FIG. 11) and the second substrate temperature measurement 610 (shown in FIG. 11) to compensate for crosstalk when power to either (or both) the laterally-inner first upper linear lamp 204 and the laterally-inner second upper linear lamp 206 is throttled.

The third substrate pyrometer 606 may also be similar to the first substrate pyrometer 600 and additionally be arranged along the third substrate pyrometer optical axis 634. The third substrate pyrometer optical axis 634 may extend from the third substrate pyrometer 606 and through a third substrate pyrometer aperture 636 defined in the upper reflector 300, between the laterally-intermediate first upper linear lamp 212 and the laterally-outer first upper linear lamp 208 of the upper heater element array 200, through the upper wall 152 of the chamber body 126 to intersect the substrate support 136 within the chamber body 126 and the substrate 2 when seated on the substrate support 136. It is further contemplated that the third substrate pyrometer optical axis 634 extend between the longitudinally-inner first lower linear lamp 404 (shown in FIG. 6) and the longitudinally-inner second lower linear lamp 406 (shown in FIG. 6), and that the third substrate pyrometer 606 have a third substrate pyrometer field of view 638. The third substrate pyrometer field of view 638 may in turn include a radially-intermediate portion of the upper surface 6 of the substrate 2 (and/or the material layer 4 during deposition thereon) located along the third substrate pyrometer optical axis 634 that is radially intermediate the first substrate pyrometer field of view 622 and the second substrate pyrometer field of 630 when the substrate 2 is seated on the substrate support 136.

It is contemplated that the third substrate pyrometer optical axis 634 intersect the substrate support 136, and the substrate 2 when seated on the substrate support 136, at a third substrate pyrometer radial offset 640 (shown in FIG. 10). The third substrate pyrometer optical axis 634 may be substantially parallel to the rotation axis 190 at least within the interior 150 of the chamber body 126 and substantially orthogonal relative to the upper surface 6 of the substrate 2 when the substrate 2 is seated on the substrate support 136. In certain examples of the present disclosure the third substrate pyrometer radial offset 640 may between about 90 millimeters and about 160 millimeters, or between about 90 millimeter and about 140 millimeters, or even between about 90 millimeters and about 110 millimeters. As will be appreciated by those of skill in the art in view of the present disclosure, third substrate pyrometer radial offsets within these ranges can simplify controlling temperature of the substrate 2 and/or the material layer 4 during deposition of the material layer 4 onto the substrate 2 using electromagnetic radiation emitted by the substrate 2 and/or the material layer 4 from within the third substrate pyrometer field of view 638, for example by limiting (or eliminating) need to compensate for crosstalk between upper linear lamps laterally offset from the laterally-intermediate first upper linear lamp 212, for example when power to such upper linear lamps is independently throttled.

It is contemplated that the chamber pyrometer 608 be configured to acquire a chamber body temperature measurement 644 (shown in FIG. 11) using electromagnetic radiation emitted by the upper wall 152 of the chamber body 126. In this respect it is contemplated that the chamber pyrometer 608 be arranged along the chamber pyrometer optical axis 652 and optically coupled to therealong to the upper wall of the chamber body 126. In further respect, it is also contemplated that the chamber pyrometer 608 be disposed in communication with the controller 108 (shown in FIG. 1), that the chamber pyrometer optical axis 652 extend between the laterally-inner first upper linear lamp 204 and the laterally-inner second upper linear lamp 206, and that the rotation axis 190 separate the chamber pyrometer optical axis 652 from the first substrate pyrometer optical axis 618. As will be appreciated by those of skill in the art in view of the present disclosure this can further simplify the chamber arrangement 104, for example by enabling linear lamp throttling cross-talk compensation employed to offset the first substrate temperature measurement 602 (shown in FIG. 11) to be employed to compensate the chamber body temperature measurement 644 acquired using the chamber pyrometer 608.

With reference to FIG. 11, the controller 108 is shown according to an example of the disclosure. It is contemplated that the controller 108 operably couple the first substrate pyrometer 600 to the upper heater element array 200 and the lower heater element array 400, for example through a power supply 642 include a silicon-controlled rectifier arrangement 648 having a plurality of silicon-controlled rectifiers individually assignable to heater elements of the upper heater element array 200 and the lower heater element array 400, using the first substrate temperature measurement 602. The controller 108 may also couple the second substrate pyrometer 604 and the third substrate pyrometer 606 to the upper heater element array 200 and/or the lower heater element array 400, for example also through the power supply 642, the second substrate temperature measurement 610 and/or the third substrate temperature measurement 612. It is further contemplated that the controller 108 may further operably couple the chamber pyrometer 608 to the chamber coolant source 198, for example using a chamber body temperature measurement 644 acquired of the chamber body 126 (shown in FIG. 3) using the chamber pyrometer 608. Operable coupling may be through the wired or wireless link 114, which may communicatively couple one or more of the aforementioned pyrometers to the controller 108 and the power supply 642 to the controller 108. Operable coupling may also be through a power bus 646, may electrically couple the upper heater element array 200 and the lower heater element array 400 as well as the chamber coolant source 198 to the power supply 642.

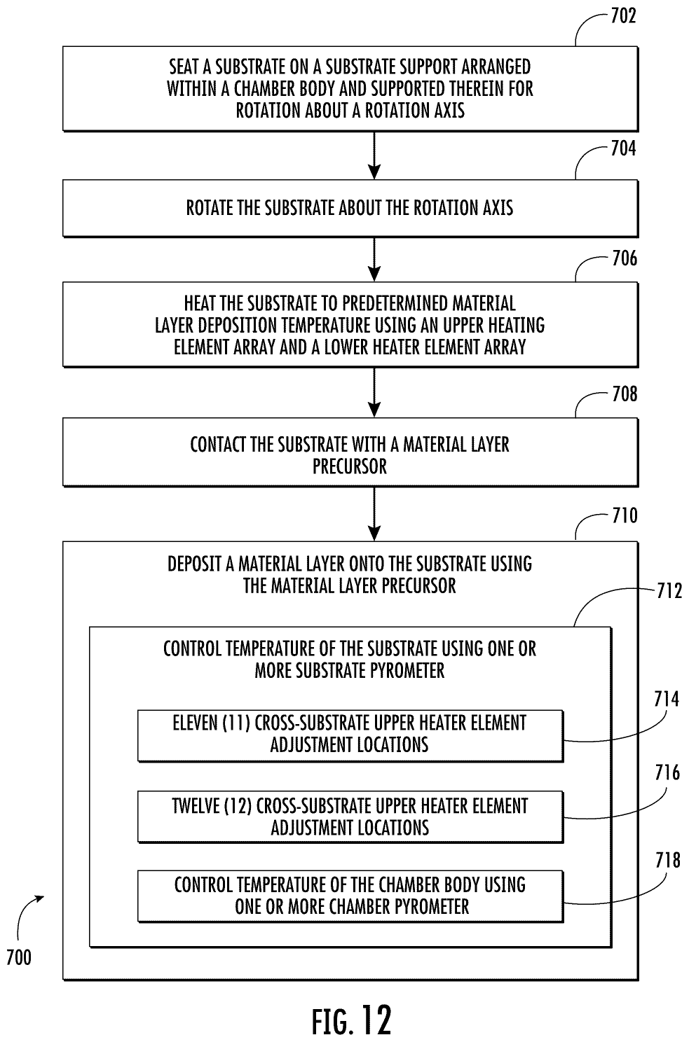

In the illustrated example the controller 108 includes a device interface 101, a processor 103, a user interface 105 and a memory 107. The device interface 101 couples the processor 103 to the chamber arrangement 104 through the wired or wireless link 114. The processor 103 is operably connected to the user interface 105, for example to receive a user input and/or provide a user output therethrough, and is disposed in communication with the memory 107. The memory 107 includes a non-transitory machine-readable medium having a plurality of program modules 109 recorded thereon that, when read by the processor 103, cause the processor 103 to execute certain operations. Among the operations are operations of material layer deposition method 700 (shown in FIG. 12), as will be described. Although shown and described herein as including certain elements and having a certain arrangement, it is to be understood and appreciated that the controller 108 may include other elements and/or exclude elements shown and described herein, or have a different arrangement in other examples and remain within the scope of the present disclosure.

With reference to FIGS. 12-15, the material layer deposition method 700 is shown. As shown in FIG. 12, the method 700 includes seating a substrate on a substrate support arranged within a chamber body and supported for rotation therein for rotation about a rotation axis, e.g., the substrate support 136 (shown in FIG. 3) arranged within the chamber body 126 (shown in FIG. 3) and supported for rotation about the rotation axis 190 (shown in FIG. 3), as shown with box 702. The method 700 also includes rotating the substrate support with the substrate seated thereon about the rotation axis and heating the substrate to a predetermined material layer deposition temperature using an upper heater element array and a lower heater element array supported above and below the chamber body, e.g., the upper heater element array 200 (shown in FIG. 3) and the lower heater element array 400 (shown in FIG. 3), as shown with box 704 and box 706. The method 700 further includes contacting the substrate with a material layer precursor, for example with a material layer precursor communicated to the chamber body via the process fluid 10 (shown in FIG. 1), and depositing a material layer onto the substrate using the using the material layer precursor, as shown with box 708 and box 710. In certain examples heating 704 the substrate and/or depositing 708 the material layer onto the substrate may include controlling temperature of the substrate using one or more pyrometer, e.g., the first substrate pyrometer 600 (shown in FIG. 3), as shown with box 712.

It is contemplated that the material layer may be deposited by contacting the substrate with a silicon-containing material layer precursor, e.g., the silicon-containing material layer precursor 16 (shown in FIG. 2), as also shown with box 710. It is also contemplated that the material layer may be deposited onto the substrate under environmental conditions to cause the material layer to deposit onto the substrate such that the material layer is epitaxial with one or more exposed surface portion of the substrate, as further shown with box 710. For example, pressure within the chamber may be maintained at a predetermined material layer deposition pressure using an exhaust source coupled to a chamber arrangement including the chamber body, e.g., the exhaust source 106 (shown in FIG. 1), that is between about 760 Torr and about 0.1 Torr, or that that is between about 700 Torr and about 0.1 Torr, or even that is between about 50 Torr and about 0.1 Torr. An upper heater array and/or a lower heater element array may heat the substrate to a predetermined material layer deposition temperature that is between about 100 degrees Celsius and about 1200 degrees Celsius, or between about 100 degrees Celsius and about 1000 degrees Celsius, or even that is between about 200 degrees Celsius and 600 degrees Celsius. Controlling temperature may be accomplished using instructions recorded in a plurality of program modules recorded on a non-transitory machine-readable medium, for example the memory 107 (shown in FIG. 2) of the controller 108 (shown in FIG. 1), as also shown with box 712.

In accordance with certain examples, controlling 712 temperature of the substrate may include throttling cross-substrate temperature variation using eleven (11) upper heater element adjustment locations distributed laterally within the chamber body and unevenly spaced apart from one another relative to the rotation axis, as shown with box 714. It is also contemplated that the controlling 712 temperature of the substrate may include throttling cross-substrate temperature variation using twelve (12) lower heater element adjustment locations distributed longitudinally within the chamber body, and that temperature of the chamber body may be controlled using a pyrometer supported above the chamber body, as shown with box 716 and box 718. In certain examples of the present disclosure controlling 712 temperature of the substrate may include operably associating a plurality of filament-type upper linear lamps of the upper heater element array with a first substrate pyrometer, e.g., operably associating the laterally-inner first upper linear lamp 204 (shown in FIG. 4) and the laterally-inner second upper linear lamp 206 (shown in FIG. 4) with the first substrate pyrometer, as also shown with box 714. In accordance with certain examples of the disclosure, controlling 712 temperature of the substrate may include operably associating a plurality of filament-type lower linear lamps of the lower heater element array with the first substrate pyrometer, e.g., operably associating the longitudinally-inner first lower linear lamp 404 (shown in FIG. 6) and the longitudinally-inner second lower linear lamp 406 (shown in FIG. 6) with the first substrate pyrometer, as also shown with box 716.

It is contemplated that controlling 712 temperature of the substrate may also include operably associating a plurality of the filament-type upper linear lamps of the upper heater element array with a second substrate pyrometer, e.g., operably associated the laterally-outer first upper linear lamp 208 (shown in FIG. 4) and the laterally-outer second upper linear lamp 210 (shown in FIG. 4) with the second substrate pyrometer 604 (shown in FIG. 3), as further shown with box 714. In accordance with certain examples, controlling 712 temperature of the substrate may also include operably associating a plurality of the filament-type lower linear lamps of the lower heater element array with the second substrate pyrometer, e.g., operably associating the longitudinally-outer first lower linear lamp 408 (shown in FIG. 6) and the longitudinally-outer second lower linear lamp 410 (shown in FIG. 6) with the second substrate pyrometer, as further shown with box 716. It is contemplated that, in accordance with certain examples of the disclosure, controlling 712 temperature of the substrate may further include operably associating a plurality of the filament-type upper linear lamps of the upper heater element array with a third substrate pyrometer, e.g., operably associating the laterally-intermediate first upper linear lamp 212 (shown in FIG. 4) and the laterally-intermediate second upper linear lamp 214 (shown in FIG. 4) with the third substrate pyrometer 606 (shown in FIG. 3), as additionally shown with box 714. It is also contemplated that controlling 712 temperature of the substrate may further include operably associating a plurality of the filament-type lower linear lamps of the lower heater element array with the third substrate pyrometer, e.g., operably associated the longitudinally-intermediate first lower linear lamp 412 (shown in FIG. 6) and the longitudinally-outer second lower linear lamp 410 (shown in FIG. 6) with the third substrate pyrometer, as additionally shown with box 716.

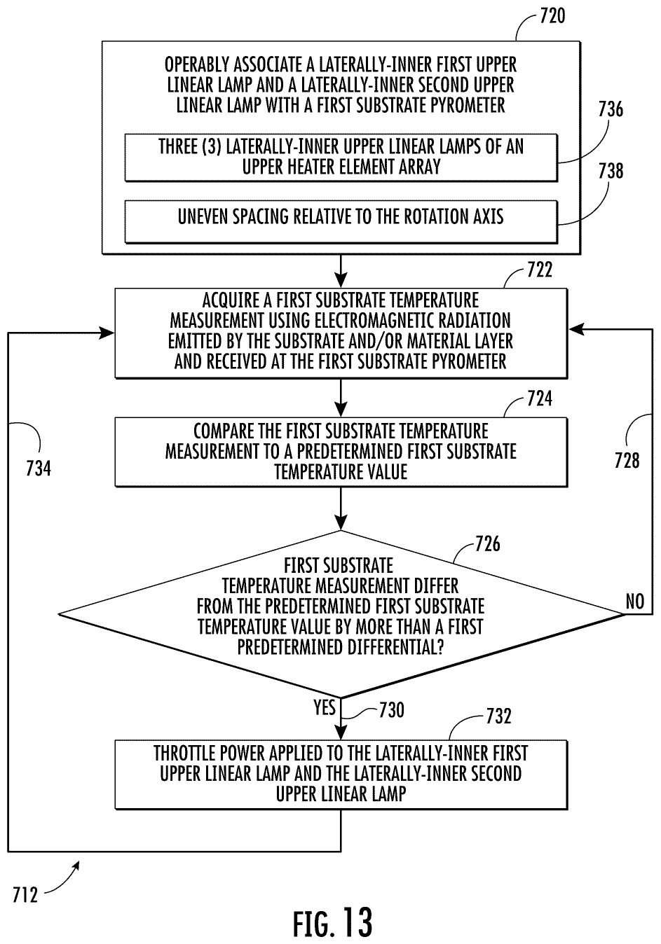

As shown in FIG. 13, controlling 712 temperature of the substrate using the upper heater element array may include operably associating a laterally-inner first upper linear lamp and a laterally-inner second upper linear lamp with a first substrate pyrometer, e.g., the laterally-inner first upper linear lamp 204 (shown in FIG. 4) and the laterally-inner second upper linear lamp 206 (shown in FIG. 4) with the first substrate pyrometer 600 (shown in FIG. 3), as shown with box 720. Controlling 712 temperature of the substrate may include acquiring a first substrate temperature measurement using electromagnetic radiation emitted by the substrate and received by the first substrate pyrometer during the heating 706 and/or the depositing 710 of the material layer onto the substrate, e.g., the first substrate temperature measurement 602 (shown in FIG. 11), as shown with box 722. It is contemplated that the first substrate temperature measurement be compared to a predetermined first substrate temperature value, as shown with box 724, and that power applied to the laterally-inner first upper linear lamp and a laterally-inner second upper linear lamp remain unchanged when the first substrate temperature measurement differs from the predetermined first temperature value by less than a predetermined first differential value, as shown with box 726 and arrow 728. It is also contemplated that power to the laterally-inner first upper linear lamp and a laterally-inner second upper linear lamp may be throttled when the first substrate temperature measurement differs from the predetermined first substrate temperature value by less than the predetermined first differential value, as shown with arrow 730 and box 732. It is further contemplated that one or more additional first substrate temperature measurement may thereafter be acquired and the aforementioned operations repeated (e.g., iteratively), as also shown with arrow 728 and further shown with arrow 734.

In certain examples, operably associating 720 the laterally-inner first upper linear lamp and the laterally-inner second upper linear lamp with the first substrate pyrometer may include operably associating a laterally-innermost three (3) upper linear lamps of the eleven (11) upper linear lamps of the upper heater element array with the first substrate pyrometer, as shown with box 736. In accordance with certain examples of the present disclosure, operably associating 720 the laterally-inner first upper linear lamp and the laterally-inner second upper linear lamp with the first substrate pyrometer may further include operably associating longitudinally-inner first lower linear lamp and a longitudinally-inner second lower linear lamp with the first substrate pyrometer, e.g., the longitudinally-inner first lower linear lamp 404 (shown in FIG. 6) and the longitudinally-inner second lower linear lamp 406 (shown in FIG. 6) of the lower heater element array, as also shown with box 736. It is also contemplated that operably associating one or more of the aforementioned upper linear lamps may include operably associating upper linear lamps unevenly spaced along a diameter of the substrate relative to the rotation axis with the first substrate pyrometer, for example to limit cross-substrate temperature variation within an interior region of the substrate underlying the upper linear lamps, as shown with box 738. Monitoring temperature of the substrate using the first substrate pyrometer may be accomplished by communicating the first substrate temperature measurement to the controller, performing the aforementioned comparison using the controller, and throttling power using one or more silicon-controlled rectifier operably associated with the controller and coupling a power source to the upper linear lamps and the lower linear lamps of the upper heater element array and the lower heater element array, respectively.

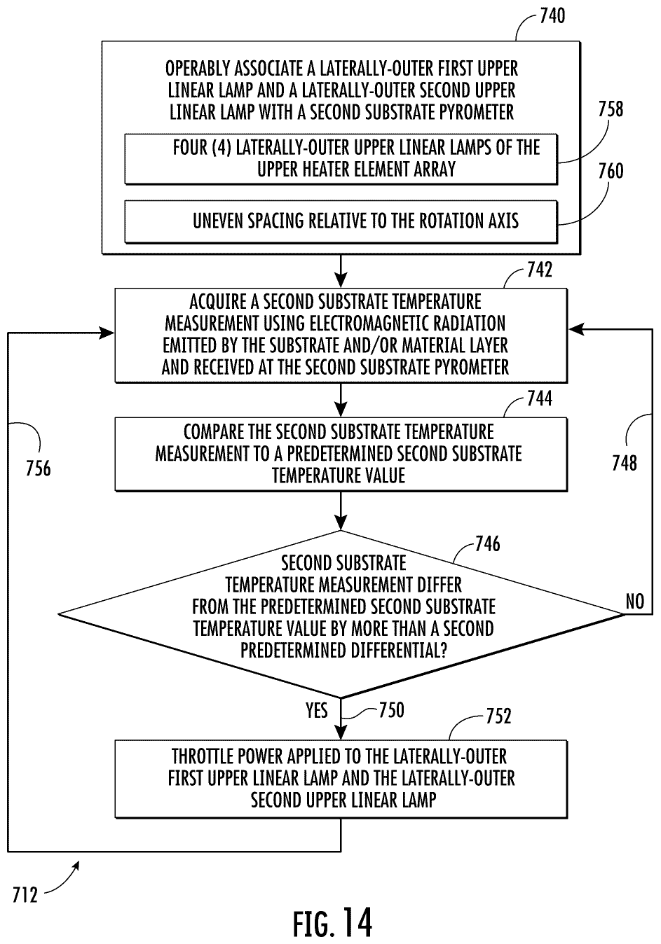

As shown in FIG. 14, controlling 712 temperature of the substrate using the upper heater element array may include operably associating a laterally-outer first upper linear lamp and a laterally-outer second upper linear lamp with a second substrate pyrometer, e.g., the laterally-outer first upper linear lamp 208 (shown in FIG. 4) and the laterally-outer second upper linear lamp 210 (shown in FIG. 4) with the second substrate pyrometer 604 (shown in FIG. 3), as shown with box 740. Controlling 712 temperature of the substrate may further include acquiring a second substrate temperature measurement using electromagnetic radiation emitted by the substrate and received by the second substrate pyrometer during the heating 706 and/or the depositing 710 of the material layer onto the substrate, e.g., the second substrate temperature measurement 610 (shown in FIG. 11), as shown with box 742. It is contemplated that the second substrate temperature measurement be compared to a predetermined second substrate temperature value, as shown with box 744, and that power applied to the laterally-outer first upper linear lamp and the laterally-outer second upper linear lamp remain unchanged when the second substrate temperature measurement differs from the predetermined second temperature value by less than a predetermined second differential value, as shown with box 746 and arrow 748. It is also contemplated that power to a laterally-outer first upper linear lamp and a laterally-outer second upper linear lamp may be throttled when the second substrate temperature measurement differs from the predetermined second substrate temperature value by less than the predetermined second differential value, as shown with arrow 750 and box 752. It is further contemplated that one or more additional second temperature measurement be acquired and aforementioned operations repeated during the heating 706 and/or the depositing 710 of the material layer onto the substrate, as also shown with arrow 754 and further shown with arrow 756.

In certain examples, operably associating 740 the laterally-outer first upper linear lamp and the laterally-outer second upper linear lamp with the second substrate pyrometer may include operably associating two laterally-outermost upper linear lamp pairs of the upper heater element array with the second substrate pyrometer, as shown with box 758. In accordance with certain examples of the present disclosure, operably associating 740 the laterally-outer first upper linear lamp and the laterally-outer second upper linear lamp with the second substrate pyrometer may further include operably associating longitudinally-outer first lower linear lamp and a longitudinally-outer second lower linear lamp of the lower heater element array with the second substrate pyrometer, e.g., the longitudinally-outer first lower linear lamp 408 (shown in FIG. 6) and the longitudinally-outer second lower linear lamp 410 (shown in FIG. 6) of the lower heater element array, as also shown with box 758. It is also contemplated that operably associating one or more of the aforementioned linear lamps may include operably associating upper linear lamps unevenly spaced along a diameter of the substrate relative to the rotation axis with the first substrate pyrometer to limit cross-substrate temperature variation, as shown with box 760. Monitoring temperature of the substrate using the second substrate pyrometer may also be accomplished by communicating the second substrate temperature measurement to the controller, performing the aforementioned comparison using the controller, and throttling power using one or more silicon-controlled rectifier operably associated with the controller and coupling a power source to the upper linear lamps and lower linear lamps of the upper heater element array and the lower heater element array, respectively.

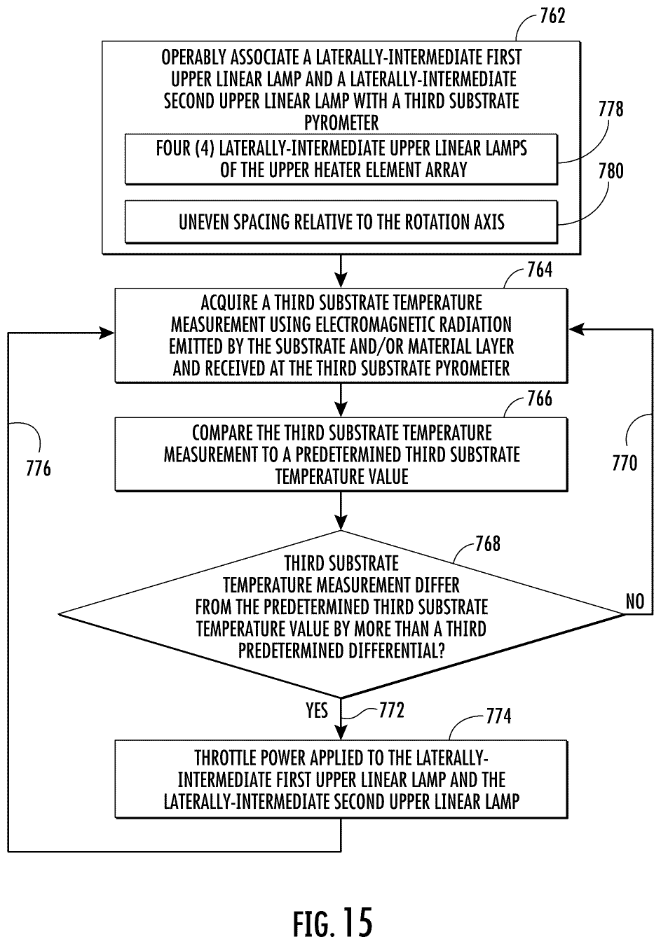

As shown in FIG. 15, controlling 712 temperature of the substrate using the upper heater element array may include operably associating a laterally-intermediate first upper linear lamp and a laterally-intermediate second upper linear lamp with a third substrate pyrometer, e.g., the laterally-intermediate first upper linear lamp 212 (shown in FIG. 4) and the laterally-intermediate second upper linear lamp 214 (shown in FIG. 4) with the third substrate pyrometer 606 (shown in FIG. 3), as shown with box 762. Controlling 712 temperature of the substrate may further include acquiring a third substrate temperature measurement using electromagnetic radiation emitted by the substrate and received by the third substrate pyrometer during the heating 706 of the substrate and/or the depositing 710 of the material layer onto the substrate, e.g., the third substrate temperature measurement 612 (shown in FIG. 11), as shown with box 764. It is contemplated that the third substrate temperature measurement be compared to a predetermined third substrate temperature value, as shown with box 766, and that power applied to the laterally-intermediate first upper linear lamp and the laterally-intermediate second upper linear lamp remain unchanged when the third substrate temperature measurement differs from the predetermined third temperature value by less than a third predetermined differential value, as shown with box 768 and with arrow 770. It is also contemplated that power to the laterally-intermediate first upper linear lamp and the laterally-outer second upper linear lamp may be throttled when the third substrate temperature measurement differs from the predetermined third substrate temperature value by less than the predetermined third differential value, as shown with arrow 772 and with box 774. It is further contemplated that one or more additional third temperature measurement be acquired and aforementioned operations repeated during the heating 706 of the substrate and/or the depositing 710 of the material layer onto the substrate, as also shown with arrow 772 and further shown with arrow 776.

In certain examples, operably associating 762 the laterally-outer first upper linear lamp and the laterally-outer second upper linear lamp with the second substrate pyrometer may include operably associating two laterally-outermost pairs of the upper heater element array with the second substrate pyrometer, as shown with box 778. In accordance with certain examples of the present disclosure, operably associating 740 the laterally-outer first upper linear lamp and the laterally-outer second upper linear lamp with the second substrate pyrometer may further include operably associating longitudinally-outer first lower linear lamp and a longitudinally-outer second lower linear lamp of the lower heater element array with the second substrate pyrometer, e.g., the longitudinally-outer first lower linear lamp 408 (shown in FIG. 6) and the longitudinally-outer second lower linear lamp 410 (shown in FIG. 6) of the lower heater element array, as also shown with box 758. It is also contemplated that operably associating one or more of the aforementioned linear lamps may include operably associating upper linear lamps unevenly spaced along a diameter of the substrate relative to the rotation axis with the first substrate pyrometer to limit cross-substrate temperature variation, as shown with box 780. Monitoring temperature of the substrate using the second substrate pyrometer may also be accomplished by communicating the second substrate temperature measurement to the controller, performing the aforementioned comparison using the controller, and throttling power using one or more silicon-controlled rectifier operably associated with the controller and coupling a power source to the upper linear lamps and lower linear lamps of the upper heater element array and the lower heater element array.

With reference to FIG. 16, graphs I and II are shown illustrating cross-substrate material layer difference between the chamber arrangement 104 (shown in FIG. 1) and another chamber arrangement, e.g., a chamber arrangement not including one or more feature include in chamber arrangement 104, for a silicon material layer and a silicon germanium material layer. As shown with arrow A and arrow B in graph I, cross-substrate material layer thickness variation of a silicon material layer deposited onto a substrate supported within chamber arrangement 104 is on the order of about 40% of cross-substrate material layer thickness variation of a silicon material layer deposited onto a substrate supported within the another chamber arrangement. As shown with arrow C and arrow D in graph II, cross-substrate material layer thickness variation of a silicon material germanium material layer deposited onto a substrate supported within chamber arrangement 104 is also on the order of about 40% of cross-substrate material layer thickness variation of a silicon germanium material layer deposited onto a substrate supported within the another chamber arrangement. Without being bound by a particular theory of mode of operation, it is believed that one or of limiting shading through the orientation of the plurality of filament-type upper linear lamps 202 (shown in FIG. 3), correspondence of the plurality of arcuate recesses 322 (shown in FIG. 4) to the plurality of filament-type upper linear lamps 202 in number and arrangement, and arrangement of the plurality of filament-type upper linear lamps 202 of relative to the upper recess profile 336 (shown in FIG. 5)—as well as other features shown and described herein-limits cross-substrate temperature variation and thereby cross-substrate material layer thickness variation within material layers deposited onto substrates within the chamber arrangement 104 in relation to than deposited onto substrates in other chamber arrangements.

With reference to FIG. 17, graphs I-III illustrating tunability of cross-substrate temperature variability through material layer thickness change are shown. As shown in graph I in FIG. 16, increase and decrease in power corresponding to a +/−2 degree Celsius substrate temperature change applied to the laterally-inner first upper linear lamp 204 (shown in FIG. 4) and the laterally-inner second upper linear lamp 206 (shown in FIG. 4) of the upper heater element array 200 (shown in FIG. 3) relative to a nominal (e.g., tuned using discrete lamp power offsets) material layer thickness using the first substrate pyrometer 600 (shown in FIG. 3) result in a thickness change with about 0.6 increase/decrease ratio in a center region of a substrate. As shown in graph II in FIG. 16, increase and decrease in power corresponding to a +/−2 degree Celsius substrate temperature change applied to the laterally-intermediate first upper linear lamp 212 (shown in FIG. 4) and the laterally-intermediate second upper linear lamp 214 (shown in FIG. 4) of the upper heater element array 200 (shown in FIG. 3) relative to the nominal material layer thickness using the third substrate pyrometer 606 result in a thickness change with about 0.8 increase/decrease ratio in an intermediate region of the substrate radially outward of the center region commensurate in magnitude with that in the center region of the substrate. As shown in graph III in FIG. 16, increase and decrease in power corresponding to a +/−2 degree Celsius substrate temperature change applied to the laterally-outer first upper linear lamp 208 (shown in FIG. 4) and the laterally-outer second upper linear lamp 210 (shown in FIG. 4) of the upper heater element array 200 (shown in FIG. 3) relative to the nominal material layer thickness using the second substrate pyrometer 604 result in thickness change with about 0.9 increase/decrease ratio in a peripheral region of the substrate radial outward of the intermediate region also commensurate in magnitude with that in the center region of the substrate. As will be appreciated by those of skill in the art in view of the present disclosure, correspondence to cross-substrate material layer thickness change enables the pyrometers to cooperatively control cross-substrate material layer thickness variation as well as substrate-to-substrate mean thickness will be consistent during sequential deposition of material layers onto substrates using the chamber arrangement 104 (shown in FIG. 1) due to reduced cross-substrate material layer variation imparted by the upper heater element array 200 and the upper reflector 300 (shown in FIG. 3).

With continuing reference to FIG. 8 and further reference to FIGS. 9 and 10, a method 800 of making a chamber arrangement, e.g., the chamber arrangement 104 (shown in FIG. 3), is shown. In the illustrated example the chamber arrangement 104 further includes one or more threaded member 654 threadedly received in an XY stage 656. The XY stage 656 extends laterally outward from the upper heater element array 200 and the upper reflector 300 and may overlie the first sidewall 156 and the second sidewall 158 of the chamber body 126. The XY stage 656 further extends longitudinally above the injection end 146 and the exhaust end 148 of the chamber body 126, and has a central aperture 658 through which the plurality of filament-type upper linear lamps 202 depending from the upper reflector 300 are optically coupled to the upper wall 152 (shown in FIG. 3) of the chamber body 126. It is contemplated that the one or more threaded member 654 be received one or more apertures defined in the upper reflector 300 and further be threadedly received within threaded apertures defined in the XY stage 656. It is contemplated that the XY stage 656 in turn be fixed relative to the chamber body 126, and the upper reflector 300 and plurality of filament-type upper linear lamps 202 depending therefrom thereby be fixed relative to the chamber body 126 with the one or more threaded member 654 is tight. It is also contemplated that the upper reflector 300 and the plurality of filament-type upper linear lamps 202 by movable laterally (e.g., toward or away from either of the first sidewall 156 and the second sidewall 158 of the chamber body 126 relative to the chamber body 126), and longitudinally (e.g., toward or away from either of the injection end 146 and the exhaust end 148 of the chamber body 126), when the one or more threaded member 654 is loosened. In the illustrated example the chamber arrangement 104 includes four (4) threaded members 654. As will be appreciated by those of skill in the art in view of the present disclosure, the chamber arrangement 104 may include fewer or additional threaded members 654.

As shown in FIG. 8, the method 800 includes supporting an upper reflector having a reflective surface above a chamber body such that the reflective surface opposes the chamber body, the reflective surface defining therein a laterally-outer first arcuate recess and a second laterally-arcuate recess separated from one another by the rotation axis, e.g., the upper reflector 300, as shown with arrow 802. As shown in FIG. 9, the upper reflector is thereafter laterally shifted such that the laterally-outer first arcuate recess is separated from the rotation axis by a first arcuate recess lateral offset and the laterally-outer second arcuate recess is separated from the rotation axis by a second arcuate recess lateral offset, the second arcuate recess lateral offset unequal to the first arcuate recess lateral offset, as shown with arrow 804. As shown in FIG. 10, the upper reflector may thereafter be longitudinally shifted such that an injection edge of the upper reflector is longitudinally offset from the rotation axis by an injection edge longitudinal offset and an exhaust edge offset of the reflector body is offset from the rotation axis by an exhaust edge longitudinal offset, the exhaust edge longitudinal offset unequal to the injection edge longitudinal offset, as shown with arrow 806. It is contemplated that laterally shifting 806 the upper reflector longitudinally increases a radial offset of a second pyrometer aperture defined in the upper reflector, and wherein longitudinally shifting the upper reflector at least in part restores the radial offset of the second pyrometer aperture.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A chamber arrangement, comprising:
a chamber body having an injection end and a longitudinally opposite exhaust end;
a substrate support arranged within the chamber body and supported therein for rotation about a rotation axis; and
an upper heater element array supported above the chamber body and including a laterally-inner first upper linear lamp and a laterally-inner second upper linear lamp,
wherein the laterally-inner first upper linear lamp is separated from the rotation axis by a first lateral spacing distance, wherein the laterally-inner second upper linear lamp is separated from the rotation axis by a second lateral spacing distance, and wherein one of the first lateral spacing distance and the second lateral spacing distance is greater than the other of the first lateral spacing distance the second lateral spacing distance.

2. The chamber arrangement of claim 1, wherein the chamber body has one or more external rib extending about an exterior of the chamber body and longitudinally between the injection end and the exhaust end of the chamber body.

3. The chamber arrangement of claim 2, wherein the laterally-inner first upper linear lamp and the laterally-inner second upper linear lamp are substantially orthogonal to the one or more external rib.

4. The chamber arrangement of claim 2, further comprising a lower heater element array including a plurality of filament-type lower linear lamps supported below the chamber body, wherein the plurality of filament-type lower linear lamps are substantially parallel to the one or more external rib.

5. The chamber arrangement of claim 1, wherein the upper heater element array is laterally offset from to the rotation axis, and wherein the upper heater element array is longitudinally offset from the rotation axis.

6. The chamber arrangement of claim 1, further comprising an upper reflector supported above the chamber body, wherein the upper heater element array is fixed relative to the chamber body, wherein the upper reflector is supported for movement relative to the chamber body.

7. The chamber arrangement of claim 1, further comprising a first substrate pyrometer supported above the chamber body and arranged along a first substrate pyrometer optical axis, the first substrate pyrometer optical axis intersecting the substrate support, the first substrate pyrometer optical axis further extending between the laterally-inner first upper linear lamp and the laterally-inner second upper linear lamp.

8. The chamber arrangement of claim 7, further comprising:
a longitudinally-inner first lower linear lamp supported below the chamber body; and
a longitudinally-inner second lower linear lamp, wherein the first substrate pyrometer optical axis extends between the longitudinally-inner first lower linear lamp and the longitudinally-inner second lower linear lamp.

9. The chamber arrangement of claim 7, further comprising a second substrate pyrometer supported above the chamber body and arranged along a second substrate pyrometer optical axis, the second substrate pyrometer optical axis intersecting the substrate support, the second substrate pyrometer optical axis extending between the laterally-inner first upper linear lamp and the laterally-inner second upper linear lamp.

10. The chamber arrangement of claim 9, further comprising:
a longitudinally-outer first lower linear lamp supported below the chamber body;
a longitudinally-intermediate second lower linear lamp supported below the chamber body, the longitudinally-intermediate second lower lamp separating the longitudinally-outer first lower linear lamp from the rotation axis; and
wherein the second substrate pyrometer optical axis extends between the longitudinally-outer first lower linear lamp and the longitudinally-intermediate second lower linear lamp.

11. The chamber arrangement of claim 7, further comprising:
a third substrate pyrometer supported above the chamber body and arranged along a third substrate pyrometer optical axis;
a longitudinally-inner first lower linear lamp supported below the chamber body;
a longitudinally-inner second lower linear lamp supported below the chamber body and separated from the longitudinally-inner first lower linear lamp by the rotation axis;
wherein the third substrate pyrometer optical axis separates the longitudinally-inner first lower linear lamp from the longitudinally-inner second lower linear lamp; and
wherein the third substrate pyrometer optical axis is separated from the laterally-inner second upper linear lamp by the laterally-inner first upper linear lamp.

12. The chamber arrangement of claim 1, wherein the chamber body comprises an upper wall and an upper rib portion formed from a singular one-piece ceramic workpiece using a subtractive manufacturing technique, and wherein the chamber body comprises a lower wall and a lower rib portion formed from a singular one-piece ceramic workpiece using a subtractive manufacturing technique.

13. The chamber arrangement of claim 1, wherein the upper heater element array includes a plurality of filament-type upper linear lamps, and wherein the chamber arrangement further comprises a lower heater element array supported below the chamber body and including a plurality of filament-type lower linear lamps, the plurality of filament-type lower linear lamps greater than the plurality of filament-type upper linear lamps.

14. A semiconductor processing system, comprising:
a chamber arrangement as recited in claim 1, further comprising:
a first substrate pyrometer supported above the chamber body and arranged along a first substrate pyrometer optical axis intersecting the substrate support;
a second substrate pyrometer supported above the chamber body and arranged along a second substrate pyrometer optical axis intersecting the substrate support;
a third substrate pyrometer supported above the chamber body and arranged along a third substrate pyrometer optical axis intersecting the substrate support; and
a controller disposed in communication with the first substrate pyrometer, the second substrate pyrometer, and the third substrate pyrometer, the controller responsive to instructions recorded on a memory to:
operably couple the first substrate pyrometer to three (3) laterally adjacent upper linear lamps of the upper heater element array including the laterally-inner first upper linear lamp and the laterally-inner second upper linear lamp;
operably couple the second substrate pyrometer to a laterally-outer first upper linear lamp and a laterally-outer second upper linear lamp of the upper heater element array;
operably couple the third substrate pyrometer to a laterally-intermediate second upper linear lamp of the upper heater element array; and
deposit a material layer onto a substrate within the chamber body while controlling temperature of the substrate using electromagnetic radiation emitted by the substrate and the material layer received at the first substrate pyrometer, the second substrate pyrometer, and the third substrate pyrometer during deposition of the material layer onto the substrate.

15. The system of claim 14, wherein the instructions cause the controller to throttle heating of the substrate using eleven (11) non-overlapping locations laterally spaced from one another above the substrate and between a first sidewall and a second sidewall of the chamber body.

16. The system of claim 14, wherein the chamber arrangement further comprises a lower heater element array including plurality of filament-type lower linear lamps substantially orthogonal to a plurality of filament-type upper linear lamps of the upper heater element array, and wherein the instructions recorded on the memory further cause the controller to:
operably couple the first substrate pyrometer to a longitudinally-inner first lower linear lamp and a longitudinally-inner second lower linear lamp of the lower heater element array;
operably couple the second substrate pyrometer to a longitudinally-outer first lower linear lamp and a longitudinally-outer second lower linear lamp of the lower heater element array; and
operably couple the third substrate pyrometer to a longitudinally-intermediate first lower linear lamp and a longitudinally-intermediate second lower linear lamp.

17. The system of claim 16, wherein the instructions cause the controller to throttle heating of the substrate using twelve (12) locations longitudinally spaced apart from one another below the substrate and between the injection end and the exhaust end of the chamber body.

18. A material layer deposition method, comprising:
at a chamber arrangement including a chamber body having an injection end and a longitudinally opposite exhaust end; a substrate support arranged within the chamber body and supported therein for rotation about a rotation axis; an upper heater element array supported above the chamber body and including a laterally-inner first upper linear lamp and a laterally-inner second upper linear lamp, the laterally-inner first upper linear lamp separated from the rotation axis by a first lateral spacing distance, the laterally-inner second upper linear lamp separated from the rotation axis by a second lateral spacing distance, and in one of the first lateral spacing distance and the second lateral spacing distance greater than the other of the first lateral spacing distance the second lateral spacing distance,
seating a substrate on the substrate support;
heating the substrate using the upper heater element array;
contacting the substrate with a material layer precursor;
depositing a material layer onto the using the material layer precursor;
wherein heating the substrate includes heating the substrate using eleven (11) filament-type upper linear heating elements offset from the rotation axis unequal lateral offsets from the rotation axis; and
whereby cross-substrate material layer thickness variation within the material layer deposited onto the substrate is less than that of a material layer deposited using a chamber arrangement having filament-type upper heater elements with two or more equivalent lateral offsets.
